(19) United States
(12) Patent Application Publication
(10) Pub. No.: US 2026/0101783 A1
(43) Pub. Date: Apr. 9, 2026

(54) SEMICONDUCTOR DEVICE AND FABRICATION METHODS THEREOF

(71) Applicant: Yangtze Memory Technologies Co., Ltd., Wuhan (CN)

(72) Inventors: Danyang WEI, Wuhan (CN); Wei LIU, Wuhan (CN); Liang CHEN, Wuhan (CN); Weiming ZHONG, Wuhan (CN); Zhengliang XIA, Wuhan (CN); Quan ZHANG, Wuhan (CN)

(21) Appl. No.: 18/949,337

(22) Filed: Nov. 15, 2024

Related U.S. Application Data
(63) Continuation of application No. PCT/CN2024/123551, filed on Oct. 9, 2024.

(51) Int. Cl. H01L 23/498; H10B 12/00

(52) U.S. Cl. CPC H10W 70/65; H10B 12/05; H10B 12/315

(57) ABSTRACT

Methods, devices, systems, and techniques for managing metal oxide metal capacitor in semiconductor devices are provided. In one aspect, a semiconductor device includes a transistor having a first terminal, a second terminal and a third terminal. The semiconductor device also includes a first interconnect layer includes a first dielectric layer and a first metal structure. The first metal structure includes a first electrode electrically coupled to the first terminal of the transistor and a second electrode electrically coupled to the third terminal of the transistor. The semiconductor device further includes a second interconnect layer includes a second dielectric layer and a second metal structure in the second dielectric layer. The semiconductor device can include a first conductive structure connected to the first metal structure and the second metal structure along the first direction and a second conductive structure connected to the second electrode of the first metal structure.

### CROSS-REFERENCE TO RELATED APPLICATIONS

This application is a continuation of International Application No. PCT/CN2024/123551, filed on Oct. 9, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The peripheral circuits can include capacitors such as metal oxide metal capacitors (MOMCAP).

### SUMMARY

The present disclosure describes methods, devices, systems and techniques for managing capacitor structures in three-dimensional (3D) semiconductor devices.

One aspect of the present disclosure features a semiconductor device. The semiconductor device includes a semiconductor structure includes a semiconductor layer and a transistor having a first terminal, a second terminal and a third terminal on a first side of the semiconductor layer. The semiconductor device also includes a first interconnect layer stacked on the first side of the semiconductor layer along a first direction, where the first interconnect layer includes a first dielectric layer and a first metal structure in the first dielectric layer, where the first metal structure includes a first electrode electrically coupled to the first terminal of the transistor and a second electrode electrically coupled to the third terminal of the transistor, where the first electrode and the second electrode are separated from each other along a second direction perpendicular to the first direction; a second interconnect layer stacked on a second side of the semiconductor layer opposite to the first side along the first direction, where the second interconnect layer includes a second dielectric layer and a second metal structure in the second dielectric layer; a first conductive structure that extends from the first interconnect layer, through the semiconductor layer, into the second interconnect layer along the first direction, where the first conductive structure is connected to the first metal structure and the second metal structure along the first direction; and a second conductive structure includes a conductive filling that is connected to the second electrode of the first metal structure.

In some implementations, the second metal structure includes a third electrode and a fourth electrode separated from each other along the second direction.

In some implementations, the second conductive structure includes an outer layer surrounded the conductive filling.

In some implementations, a portion of the outer layer in the semiconductor layer includes a high-k material, and a remaining portion of the outer layer of the second conductive structure includes a dielectric material, and where a dielectric constant of the high-k material is greater than a dielectric constant of the dielectric material.

In some implementations, the second conductive structure extends from the first interconnect layer into the semiconductor layer, and where, along the first direction, a length of the second conductive structure is no greater than a length of the first conductive structure.

In some implementations, the first conductive structure includes an inner body and an outer layer, where the inner body of the first conductive structure includes a conductive material and the outer layer of the first conductive structure includes a dielectric material.

In some implementations, the second conductive structure extends continuously or intermittently, and where the second conductive structure surrounds the transistor.

In some implementations, the semiconductor device further includes a third metal structure in the first interconnect layer having a fifth electrode and a sixth electrode separated from each other, where the third metal structure is stacked between the semiconductor structure and the first metal structure along the first direction, and the third metal structure is spaced from the semiconductor layer and the first metal structure along the first direction, and where the first electrode of the first metal structure is electrically coupled to the first terminal of the transistor through the fifth electrode and the second electrode of the first metal structure is electrically coupled to the third terminal of the transistor through the sixth electrode.

In some implementations, the first electrode and the second electrode of the first metal structure have a plurality of electrical fingers alternating with each other along a third direction perpendicular to the first direction and the second direction, and where the third electrode and the fourth electrode of the second metal structure have a plurality of electrical fingers alternating with each other along the third direction.

In some implementations, the second conductive structure extends from the first interconnect layer, through the semiconductor layer, into the second interconnect layer, and where the conductive filling of the second conductive structure is connected to one of the electrodes of the second metal structure along the first direction.

In some implementations, the second conductive structure extends from the first interconnect layer, through the semiconductor structure, into the second interconnect layer, and where the conductive filling of the second conductive structure is connected to one of the electrodes of the second metal structure along the first direction.

In some implementations, the second conductive structure extends through the first terminal of the transistor, the second terminal of the transistor and the semiconductor layer, where a portion of the outer layer of the second conductive structure extends through the first terminal and the second terminal of the transistor includes the high-k material, and where the first terminal and the second terminal of the transistor is in contact with the outer layer of the second conductive structure along the second direction.

Another aspect of the present disclosure features a method of forming a semiconductor device. The method includes forming a semiconductor structure includes a semiconductor layer and a transistor having a first terminal, a second terminal and a third terminal on a first side of the semiconductor layer. The method also includes forming a first interconnect layer stacked on the first side of the semiconductor layer along a first direction, where the first interconnect layer includes a first dielectric layer and a first metal structure in the first dielectric layer, where the first metal structure includes a first electrode electrically coupled to the first terminal of the transistor and a second electrode electrically coupled to the third terminal of the transistor, where the first electrode and the second electrode are separated from each other along a second direction perpendicular to the first direction; forming a second interconnect layer stacked on a second side of the semiconductor layer opposite to the first side along the first direction, where the second interconnect layer includes a second dielectric layer and a second metal structure in the second dielectric layer; forming a first conductive structure that extends from the first interconnect layer, through the semiconductor layer, into the second interconnect layer along the first direction, where the first conductive structure is connected to the first metal structure and the second metal structure along the first direction; and forming a second conductive structure includes a conductive filling that is connected to the second electrode of the first metal structure.

In some implementations, forming the transistor includes etching a portion of the semiconductor layer along the first direction to form first spaces; etching a portion of the semiconductor layer along the first direction to form a second space, where the second space and the first spaces are separated from each other along the second direction; filling a dielectric material into the first spaces and the second space to from first filled spaces and a second filled space; and forming the transistor having a first terminal, a second terminal and a third terminal between two adjacent first filled spaces along the second direction.

In some implementations, the second conductive structure extends from the first interconnect layer into the semiconductor layer, and where the method further includes etching a third portion of the semiconductor layer along the first direction to form a third space, where the third space, the first filled spaces, and the second filled space are separated from each other; depositing a high-k material on an inner wall of the third space; filling a conductive material into the third space to form the second conductive structure; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor and is connected to the conductive filling of the second conductive structure; depositing the second interconnect layer on the second side of the semiconductor layer opposite to the first side along the first direction; etching a portion of the second interconnect layer, the second filled space, and the first interconnect layer along the first direction to form a fourth space connected to the first electrode of the first metal structure; depositing a conductive material in the fourth space to form the first conductive structure; and forming the second metal structure having a third electrode and a fourth electrode separated from each other in the second interconnect layer, where the first conductive structure is connected to the first metal structure and the second metal structure along the first direction.

In some implementations, the second conductive structure extends continuously or intermittently, and where the second conductive structure surrounds the transistor.

In some implementations, the second conductive structure extends from the first interconnect layer, through the semiconductor layer, into the second interconnect layer, and where the method further includes etching a portion of the semiconductor layer along the first direction to form a fifth space, where the fifth space, the first filled spaces, and the second filled space are separated from each other; depositing a high-k material on an inner wall of the fifth space; filling the fifth space with a dielectric material to from a fifth filled space; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor; depositing the second interconnect layer on the second side of the semiconductor layer opposite to the first side along the first direction; etching a portion of the second interconnect layer, the second filled space, and the first interconnect layer along the first direction to form a sixth space connected to the first electrode of the first metal structure; etching a portion of the second interconnect layer, the semiconductor layer, the fifth filled space, and the first interconnect layer to from a seventh space connected to the second electrode of the first metal structure; depositing a conductive material in the sixth space and the seventh space to from the first conductive structure and the second conductive structure; and forming the second metal structure having a third electrode and a fourth electrode separated from each other in the second interconnect layer, where the first conductive structure is connected to the first metal structure and the second metal structure along the first direction, and where the second conductive structure is connected to the second electrode of the first metal structure and one of the electrodes of the second metal structure.

In some implementations, the second conductive structure extends through the first terminal of the transistor, the second terminal of the transistor, the semiconductor layer and into the second interconnect layer, and where the method further includes etching a portion of the semiconductor layer along the first direction to form an eighth space, where the eighth space, the first filled spaces, and the second filled space are separated from each other, and where the eighth space is between the two adjacent first filled spaces and the eighth space extends through the first terminal and the second terminal of the transistor; depositing a high-k material on an inner wall of the eighth space; filling the eighth space with a dielectric material to from an eighth filled space, where the eighth filled space is between two adjacent first filled space; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor; depositing the second interconnect layer on the second side of the semiconductor layer opposite to the first side along the first direction; etching a portion of the second interconnect layer, the second filled space, and the first interconnect layer along the first direction to form a ninth space connected to the first electrode of the first metal structure; etching a portion of the second interconnect layer, the semiconductor layer, the eighth filled space, and the first interconnect layer to from a tenth space connected to the second electrode of the first metal structure; depositing a conductive material in the ninth space and the tenth space to from the first conductive structure and the second conductive structure; and forming the second metal structure having a third electrode and a fourth electrode separated from each other in the second interconnect layer, where the first conductive structure is connected to the first metal structure and the second metal structure along the first direction, and where the second conductive structure is connected to the second electrode of the first metal structure and one of the electrodes of the second metal structure.

In some implementations, the method further includes forming a third metal structure in the first interconnect layer having a fifth electrode and a sixth electrode separated from each other, where the third metal structure is stacked between the semiconductor layer and the first metal structure along the first direction, and the third metal structure is spaced from the semiconductor layer and the first metal structure along the first direction, and where the first electrode of the first metal structure is electrically coupled to the first terminal of the transistor through the fifth electrode and the second electrode of the first metal structure is electrically coupled to the third terminal of the transistor through the sixth electrode.

A further aspect of the present disclosure features a memory system. The memory system includes a memory device and a memory controller coupled to the memory device and configured to control the memory device. The memory device includes a semiconductor structure includes a semiconductor layer and a transistor having a first terminal, a second terminal and a third terminal on a first side of the semiconductor layer; a first interconnect layer stacked on the first side of the semiconductor layer along a first direction, where the first interconnect layer includes a first dielectric layer and a first metal structure in the first dielectric layer, where the first metal structure includes a first electrode electrically coupled to the first terminal of the transistor and a second electrode electrically coupled to the third terminal of the transistor, where the first electrode and the second electrode are separated from each other along a second direction perpendicular to the first direction; a second interconnect layer stacked on a second side of the semiconductor layer opposite to the first side along the first direction, where the second interconnect layer includes a second dielectric layer and a second metal structure in the second dielectric layer; a first conductive structure that extends from the first interconnect layer, through the semiconductor layer, into the second interconnect layer along the first direction, where the first conductive structure is connected to the first metal structure and the second metal structure along the first direction; and a second conductive structure includes a conductive filling that is connected to the second electrode of the first metal structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2A illustrates a cross-sectional view of an example 3D semiconductor device.

FIGS. 2B-2D illustrate top views of the example 3D semiconductor device of FIG. 2A.

FIG. 3A illustrates a cross-sectional view of an example 3D semiconductor device.

FIGS. 3B-3D illustrate top views of the example 3D semiconductor device of FIG. 3A.

FIG. 4A illustrates a cross-sectional view of an example 3D semiconductor device.

FIGS. 4B-4E illustrate top views of the example 3D semiconductor device of FIG. 4A.

FIGS. 5A-5O show cross-sectional views of structures of a 3D semiconductor device of FIG. 2A at various stages of a fabrication process.

FIGS. 6A-6O show cross-sectional views of structures of a 3D semiconductor device of FIG. 3A at various stages of a fabrication process.

FIG. 7 illustrates a flow chart of an example process of manufacturing a semiconductor structure.

FIG. 8 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a DRAM memory) can be formed to have an increased array density and a reduced dimension of the array wafer. To maximize the utilization of the array wafer, the capacitors are fabricated in the CMOS wafer. A target capacitance is required for the capacitors in the CMOS wafer to maintain the ideal operating condition of the memory array. The array wafer and the CMOS wafer are fabricated separately and bonded together during the fabrication process of the memory device. As a result of the reduction in the dimension of the array wafer, the dimension of the CMOS wafer, which includes the capacitor, is also reduced to match the array wafer. The reduction in the CMOS wafer dimensions leads to a lower capacitance of the metal oxide metal capacitor (MOMCAP). Therefore, a new structure of the MOMCAP in the CMOS wafer that can maintain the target capacitance for the ideal operating condition of the memory array is desirable.

In one or more implementations of the present disclosure, an example semiconductor device is provided. The semiconductor device includes a semiconductor structure includes a semiconductor layer and a transistor having a first terminal, a second terminal and a third terminal on a first side of the semiconductor layer. The semiconductor device also includes a first interconnect layer stacked on the first side of the semiconductor layer along a first direction, where the first interconnect layer includes a first dielectric layer and a first metal structure in the first dielectric layer, where the first metal structure includes a first electrode electrically coupled to the first terminal of the transistor and a second electrode electrically coupled to the third terminal of the transistor, where the first electrode and the second electrode are separated from each other along a second direction perpendicular to the first direction. The semiconductor device further includes a second interconnect layer stacked on a second side of the semiconductor layer opposite to the first side along the first direction, where the second interconnect layer includes a second dielectric layer and a second metal structure in the second dielectric layer. The semiconductor device can include first conductive structure that extends from the first interconnect layer, through the semiconductor layer, into the second interconnect layer along the first direction, where the first conductive structure is connected to the first metal structure and the second metal structure along the first direction. The semiconductor device can also include a second conductive structure includes a conductive filling that is connected to the second electrode of the first metal structure.

Implementations of the present disclosure can provide one or more of the following technical advantages and/or benefits. First, the metal structures are located on both sides of the transistors to increase the density of the MOMCAP. In other words, the first metal structure and the second metal structure are connected via the first conductive structure to increase the capacitance of the MOMCAP. Second, the second conductive structure connected to the first metal structure also leads to an overall increase in the capacitor density of the MOMCAP within the same device dimension, which results in an increase in the capacitance of the MOMCAP. Therefore, the target capacitance of the MOMCAP can be achieved by combining the capacitor density provided by the dual-side metal structures and the second conductive structures in the semiconductor layer.

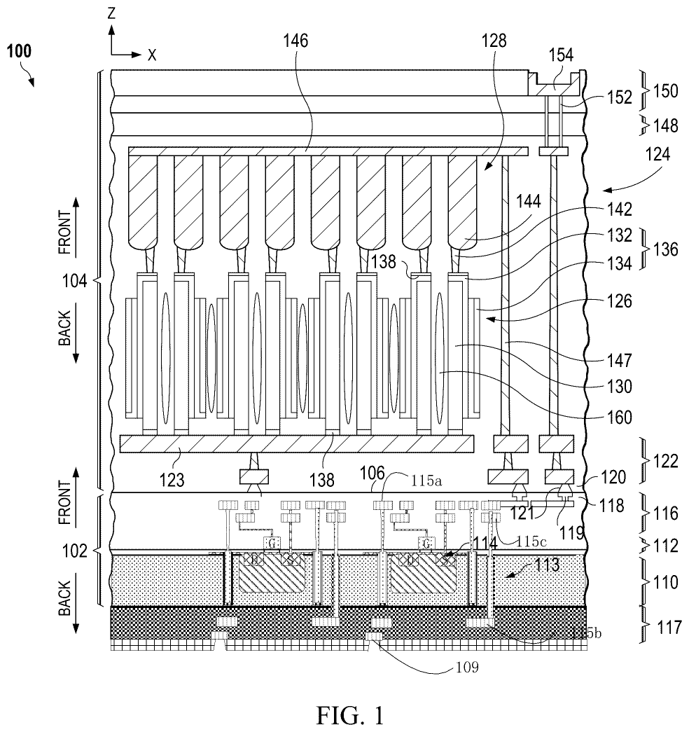

FIG. 1 illustrates a side view of a cross-section of an example 3D semiconductor device 100. It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween. In some implementations, as shown in FIG. 1A, the 3D semiconductor device 100 can be a volatile memory device such as a 3D dynamic random-access memory (DRAM). In some implementations (not shown in FIG. 1), the semiconductor device 100 can be a video random-access memory (VRAM) or a non-volatile memory (NVM) device such as NAND flash memory or ferroelectric random-access memory (FeRAM).

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of metal oxide metal capacitors (MOMCAP) 113. Each MOMCAP 113 can include a transistor 114 (e.g., metal oxide semiconductor capacitor (MOScap) and/or 3D transistors) and a plurality of metal structures 115a, 115b, and 115c. Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102. In some implementations, the metal structures 115a, 115b, and 115c can be used as a capacitor to increase the overall capacitance of the MOMCAP 113.

In some implementations, the first semiconductor structure 102 further includes a first interconnect layer 116 and a second interconnect layer 117 on opposite sides of the peripheral circuits 112 along the Z direction to transfer electrical signals to and from the peripheral circuits 112. In some implementations, the interconnect layers 116 and 117 can include metal structures 115a, 115b, and 115c of the MOMCAP 113. In some implementations, the interconnect layers 116, 117 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. In some implementations, the second interconnect layer 117 can include a plurality of pad-out structures 109 coupled to the MOMCAP 113. The plurality of pad-out structures 109 in the second interconnect layer 117 are configured to transfer electrical signals to and from the MOMCAP 113. In some implementations, multiple pad-out structures 109 are coupled to the MOMCAP 113, where each pad-out structure 109 is couple to a corresponding device that transfers electrical signal to and from the MOMCAP 113. The metal structures 115a, 115b, and 115c, the pad out structures 119, and the interconnects in interconnect layers 116 and 117 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

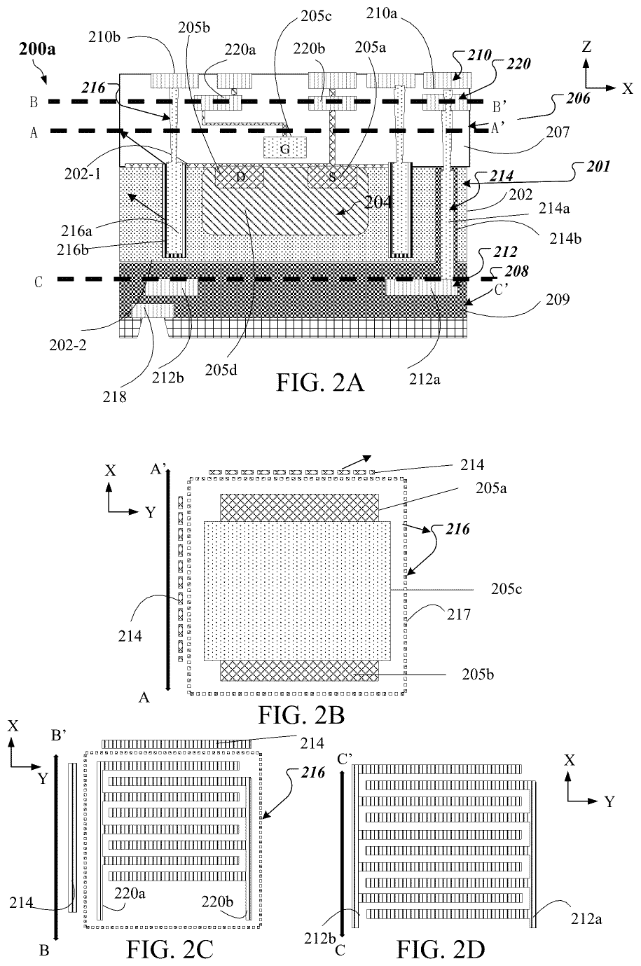

FIG. 2A illustrates across-sectional view (e.g., in the XZ plane) of example 3D semiconductor device 200a. One or more of 3D semiconductor devices 200a can be similar to, or same as, a part of the 3D semiconductor device 100 of FIG. 1 (e.g., the MOMCAP 113 of FIG. 1).

As shown in FIG. 2A, the semiconductor device 200a includes a semiconductor structure 201. The semiconductor structure 201 can include a semiconductor layer 202 and a transistor 204 having a first terminal 205a, a second terminal 205b and a third terminal 205c on a first side 202-1 of the semiconductor layer. In some implementations, the transistor 204 can include a well region 205d that extends into the semiconductor layer 202 along the first direction. In some implementations, the well region 205d can include a heavily doped semiconductor material such as negatively doped silicon and the semiconductor layer 202 can include a semiconductor material such as undoped silicon. In some implementations, the transistor 204 can be similar to, or same as the transistor 114 of FIG. 1. In some implementations, the transistor 204 can be a MOScap and the first terminal 205a of the transistor can be either a source terminal or a drain terminal, the second terminal 205b of the transistor can be either a source terminal or a drain terminal, and the third terminal 205c can be a gate terminal. For example, as shown in FIG. 2A, the first terminal 205a of the transistor 204 is a source terminal, the second terminal 205b of the transistor 204 is a drain terminal, and the third terminal 205c of the transistor 204 is a gate terminal. In some implementations, the third terminal 205c and the second terminal 205b are electrically coupled together.

The semiconductor device 200a can include a first interconnect layer 206 having a first dielectric layer 207 and a first metal structure 210 in the first dielectric layer 207. In some implementations, the first interconnect layer 206 is stacked on the first side 202-1 of the semiconductor layer 202 along a vertical direction (e.g., the Z direction). In some implementations, the first interconnect layer 206 can be similar to, or same as the first interconnect layer 116 of FIG. 1. The first metal structure 210 includes a first electrode 210a electrically coupled to the first terminal 205a of the transistor 204 and a second electrode 210b electrically coupled to the third terminal 205c of the transistor 204. The first electrode 210a and the second electrode 210b of the first metal structure 210 are separated from each other along a first horizontal direction (e.g., the X-direction) perpendicular to the Z direction. In some implementations (not shown in FIG. 2A), the first interconnect layer 206 can include multiple first dielectric layers 207 stacked on top of each other along the Z direction and a plurality of first metal structure 210 in the corresponding first dielectric layer 207. Each first dielectric layers 207 can include a dielectric material such as SiO2, SiN, TiN. In some implementations, the first metal structure 210 can be formed with conductive materials including, but not limited to, W, Co, Cu, Al, silicides, or any combination thereof.

In some implementations, the first metal structure 210 can be used as a metal-oxide-metal capacitor (MOMCAP) to increase the capacitance of the semiconductor device 200a. In some implementations, the first electrode 210a and the second electrode 210b of the first metal structure 210 have a plurality of electrical fingers alternating with each other along a second horizontal direction (e.g., the Y direction) perpendicular to the X direction and the Z direction. In some implementations, a number of pluralities of electrical fingers can be adjusted based on the targe capacitance of the MOMCAP, where the capacitance of the MOMCAP increases as the number of the plurality of alternating electrical fingers for the electrodes 210a and 210b of the first metal structure 210 increases. In some implementations, the electrical fingers of the first metal structure 210 extends along the Y direction in a straight line. In some implementations, the electrical fingers of the first metal structure 210 extends along the Y direction in a wave shape line. In some implementations, the first metal structure 210 can be similar to, or same as the metal structure 115a of FIG. 1.

The semiconductor device 200a can further include a second interconnect layer 208 stacked on a second side 202-2 of the semiconductor layer 202 opposite to the first side 202-1 along the Z direction. The second interconnect layer 208 can include a second dielectric layer 209 and a second metal structure 212 in the second dielectric layer 209. In some implementations, the second interconnect layer 208 can be similar to, or same as the second interconnect layer 117 of FIG. 1. In some implementations (not shown in FIG. 2A), the second interconnect layer 208 can include multiple second dielectric layers 209 stacked on top of each other along the Z direction and a plurality of second metal structure 212 in the corresponding second dielectric layer 209. Each second dielectric layers 209 can include a dielectric material such as SiO2, SiN, TiN. In some implementations, the second metal structure 212 can be used as a MOMCAP to increase the capacitance of the semiconductor device 200a. In some implementations, the second metal structure 212 can include a third electrode 212a and a fourth electrode 212b separated from each other along the X direction. In some implementations, the second metal structure 212 can be formed with conductive materials including, but not limited to, W, Co, Cu, Al, silicides, or any combination thereof.

As shown in FIG. 2A, the semiconductor device 200a can further include a first conductive structure 214 that extends from the first interconnect layer 206, through the semiconductor layer 202, into the second interconnect layer 208 along the Z direction. In some implementations, the first metal structure 210 and the second metal structure 212 are electrically coupled together through the first conductive structure 214. For example, as shown in FIG. 2A, the first electrode 210a of the first metal structure 210 and the third electrode 212a of the second metal structure 212 are electrically coupled together through the first conductive structure 214. In some implementations, the first conductive structure can be a through silicon contact that extends through the semiconductor layer 202. In some implementations, as shown in FIG. 2A, the first conductive structure 214 includes an inner body 214a and an outer layer 214b. The inner body 214a the first conductive structure 214 can include conductive materials including, but not limited to, W, Co, Cu, Al, silicides, or any combination thereof. The outer layer 214b of the first conductive structure 214 can be formed with dielectric materials including, but not limited to, silicon oxide, silicon nitride, silicon oxynitride, low-k dielectrics, or any combination thereof. In some implementations, the second metal structure 212 can be similar to, or same as the metal structure 115b of FIG. 1.

In some implementations, as shown in FIG. 2A, the semiconductor device 200a can include a second conductive structure 216 connected to the second electrode 210b of the first metal structure 210. In some implementations, as shown in FIG. 2A, the second conductive structure 216 extends from the first interconnect layer 206 into the semiconductor layer 202, where, along the Z direction, a length of the second conductive structure 216 is no greater than a length of the first conductive structure 214. In some implementations, the second conductive structure includes a conductive filling 216a and an outer layer 216b surrounded the conductive filling 216a. The conductive filling 216a of the second conductive structure 216 can include conductive materials including, but not limited to, W, Co, Cu, Al, silicides, or any combination thereof. In some implementations, as shown in FIG. 2A, a portion of the outer layer 216b of the second conductive structure 216 in the semiconductor layer 202 can be formed with a high-k material including, but not limited to, hafnium dioxide (HfO2), Zirconium dioxide (ZrO2) and titanium dioxide (TiO2) and a remaining portion of the outer layer 216b of the second conductive structure 216 can be formed with dielectric materials including, but not limited to, silicon oxide, silicon nitride, silicon oxynitride, low-k dielectrics, or any combination thereof. A dielectric constant of the high-k material in the portion of the outer layer 216b of the second conductive structure 216 in the semiconductor layer 202 is greater than a dielectric constant of the dielectric material in the remaining portion of the outer layer 216b of the second conductive structure 216. In some implementations, the second conductive structure 216 can be a bottom deep trench isolation (BDTI) structure that is used to increase the capacitance of the semiconductor device 200a. In some implementations, the second interconnect layers can include a plurality of pad-out structures 218 coupled to the second metal structure 212, where the pad-out structures 218 are configured to transfer electrical signals to and from the semiconductor device 200a.

FIG. 2B illustrates a top view of the example 3D semiconductor device 200a of FIG. 2A along cut line AA′ of FIG. 2A. As shown in FIG. 2B, the second conductive structure 216 surrounds the transistor 204 in a ring structure. The ring structure of the second conductive structure 216 is between the first conduction structure 214 and the transistor 204. In some implementations (not shown in FIG. 2B), the first conductive structure 214 is between the ring structure of the second conductive structure 216 and the transistor 204. In some implementations, the second conductive structure 216 is partially surrounding the transistor 204. In some implementations, as shown in FIG. 2B, the second conductive structure 216 can include a plurality of vias 217 that extend into the semiconductor layer 202, where the second conductive structure 216 extends intermittently along the horizontal directions. In some implementations (not shown in FIG. 2B), the second conductive structure 216 can include a single trench that extend continuously along the horizontal directions. In some implementations, a number of second conductive structure 216 that surrounds the transistor 204 is not limited to one, where a higher number of second conductive structures 216 surround the transistor 204 corresponding to an increase in the capacitance of the semiconductor device 200a.

FIG. 2C illustrates a top view of the example 3D semiconductor device 200a of FIG. 2A along cut line BB′ of FIG. 2A. In some implementations, the semiconductor device 200a can further include a third metal structure 220 having a fifth electrode 220a and a sixth electrode 220b separated from each other. As shown in FIG. 2A, the third metal structure 220 is stacked between the semiconductor structure 201 and the first metal structure 210 in the first interconnect layer 206 along the Z direction. In some implementations, the third metal structure 220 is spaced from the semiconductor layer and the first metal structure along the Z direction. In some implementations, as shown in FIG. 2A, the first electrode 210a of the first metal structure 210 is electrically coupled to the first terminal 205a of the transistor 204 through the fifth electrode 220a of the third metal structure 220 and the second electrode 210b of the first metal structure 210 is electrically coupled to the third terminal 205c of the transistor 204 through the sixth electrode 220b of the third metal structure 220. In some implementations, the third metal structure 220 can be formed with a conductive material with a high resistance such as TiN, where a resistance of the conductive material of the third metal structure 220 is higher than a resistance of the conductive material of the first metal structure 210. In some implementations, the third metal structure 220 can be used as a MOMCAP to increase the capacitance of the semiconductor device 200a. In some implementations, as shown in FIG. 2C, the fifth electrode 220a and the sixth electrode 220b of the third metal structure 220 have a plurality of electrical fingers alternating with each other along a second horizontal direction (e.g., the Y direction) perpendicular to the X direction and the Z direction. In some implementations, a number of pluralities of electrical fingers of the third metal structure 220 can be adjusted based on the targe capacitance of the MOMCAP, where the capacitance of the MOMCAP increases as the number of the plurality of alternating electrical fingers for the electrodes 220a and 220b of the third metal structure 220 increases. In some implementations, as shown in FIG. 2C, the electrical fingers of the third metal structure 220 extends along the Y direction in a straight line. In some implementations (not shown in FIG. 2C), the electrical fingers of the third metal structure 220 extends along the Y direction in a wave shape line. In some implementations, the third metal structure 220 is coupled to power sources that apply power to the MOMCAP. In some implementations, the third metal structure 220 can be similar to, or same as the metal structure 115c of FIG. 1.

FIG. 2D illustrates a top view of the example 3D semiconductor device 200a of FIG. 2A along cut line BB′ of FIG. 2A. In some implementations, the second metal structure 212 can be used as a MOMCAP to increase the capacitance of the semiconductor device 200a. As shown in FIG. 2D, the third electrode 212a and the fourth electrode 212b of the second metal structure 212 have a plurality of electrical fingers alternating with each other along a second horizontal direction (e.g., the Y direction) perpendicular to the X direction and the Z direction. In some implementations, a number of pluralities of electrical fingers of the second metal structure 212 can be adjusted based on the targe capacitance of the MOMCAP, where the capacitance of the MOMCAP increases as the number of the plurality of alternating electrical fingers for the electrodes 212a and 212b of the second metal structure 212 increases. In some implementations, as shown in FIG. 2B, the electrical fingers of the second metal structure 212 extends along the Y direction in a straight line. In some implementations (not shown in FIG. 2B), the electrical fingers of the second metal structure 212 extends along the Y direction in a wave shape line.

In some implementations, the MOMCAP of the semiconductor device 200a can include the first metal structure 210, the second metal structure 212, the third metal structure 220 and the second conductive structure 216. The semiconductor device 200a can be a MOMCAP 113 of FIG. 1, where the capacitance of the semiconductor device 200a is determined according to the capacitance of the MOMCAP and the transistor 204.

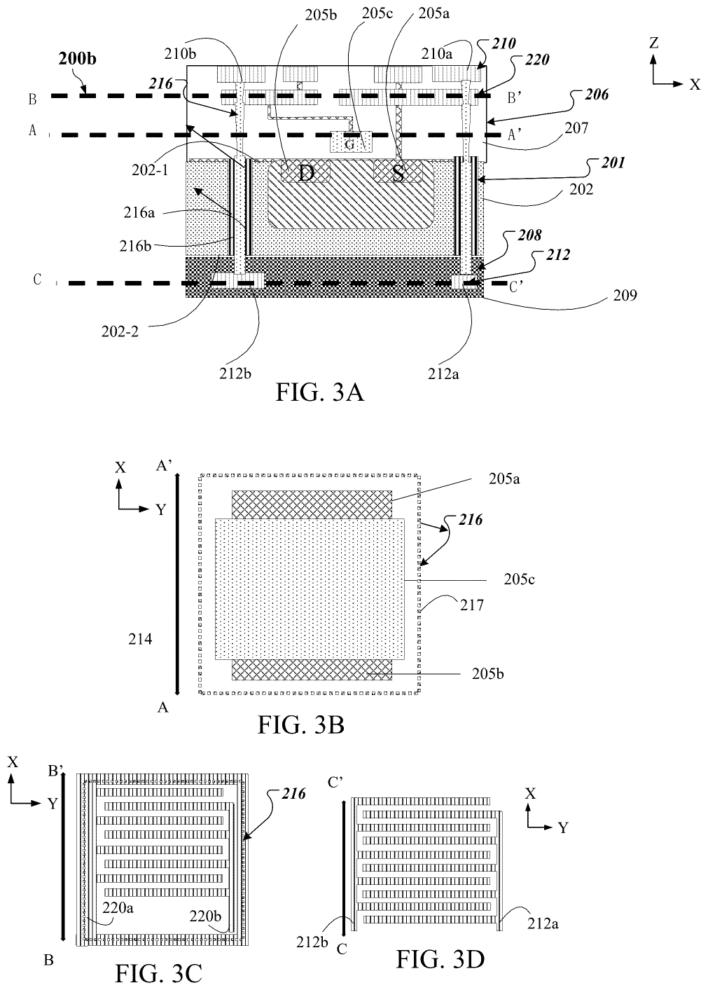

FIG. 3A illustrates across-sectional view (e.g., in the XZ plane) of example 3D semiconductor device 200b. One or more of 3D semiconductor devices 200b can be similar to, or same as, a part of the 3D semiconductor device 100 of FIG. 1 (e.g., the MOMCAP 113 of FIG. 1). The semiconductor device 200b can be similar to the semiconductor device 200a of FIG. 2A except for the second conductive structure 216.

As shown in FIG. 3A, the second conductive structures 216 extends from the first interconnect layer 206, through the semiconductor layer 202, into the second interconnect layer 208. The second conductive structure 216 is spaced from the transistor 204. In some implementations, the conductive fillings 216a of the second conductive structures 216 is connected to one or the electrodes 212a, 212b of the second metal structure 212 and the second electrode 210b of the first metal structure 210 along the Z direction. In some implementations (not shown in FIG. 3A), the semiconductor device 200b can include a first conductive structure 214, where a length of the second conductive structure 216 of the semiconductor device 200b equals to a length of the first conductive structure 214.

FIG. 3B illustrates a top view of the example 3D semiconductor device 200b of FIG. 3A along cut line AA′ of FIG. 3A. As shown in FIG. 3B, the second conductive structure 216 surrounds the transistor 204 in a ring structure. In some implementations, as shown in FIG. 3B, the second conductive structure 216 can include a plurality of vias 217 that extend into the semiconductor layer 202, where the second conductive structure 216 extends intermittently along the horizontal directions. In some implementations (not shown in FIG. 3B), the second conductive structure 216 can include a single trench that extend continuously along the horizontal directions. In some implementations, the second conductive structure 216 is partially surrounding the transistor 204. In some implementations, a number of second conductive structure 216 that surrounds the transistor 204 is not limited to one, where a higher number of second conductive structures 216 surround the transistor 204 corresponding to an increase in the capacitance of the semiconductor device 200a.

FIG. 3C illustrates a top view of the example 3D semiconductor device 200b of FIG. 3A along cut line BB′ of FIG. 3A. In some implementations, the semiconductor device 200c can further include a third metal structure 220. As shown in FIG. 3A, the third metal structure 220 is stacked between the semiconductor structure 201 and the first metal structure 210 in the first interconnect layer 206 along the Z direction. As shown in FIG. 3A, the second conductive structure 216 extends through the third metal structure 220 along the Z direction. In some implementations, as shown in FIG. 3C, third metal structure 220 can include a fifth electrode 220a and a sixth electrode 220b separated from each other along the Y direction. In some implementations, as shown in FIG. 3C, the second conductive structure is connected to the fifth electrode 220a of the third metal structure 220. The fifth electrode 220a and the sixth electrode 220b of the third metal structure 220 have a plurality of electrical fingers alternating with each other along a second horizontal direction (e.g., the Y direction) perpendicular to the X direction and the Z direction.

FIG. 3D illustrates a top view of the example 3D semiconductor device 200b of FIG. 3A along cut line CC′ of FIG. 3A. As shown in FIG. 3D, the third electrode 212a and the fourth electrode 212b of the second metal structure 212 have a plurality of electrical fingers alternating with each other along a second horizontal direction (e.g., the Y direction) perpendicular to the X direction and the Z direction.

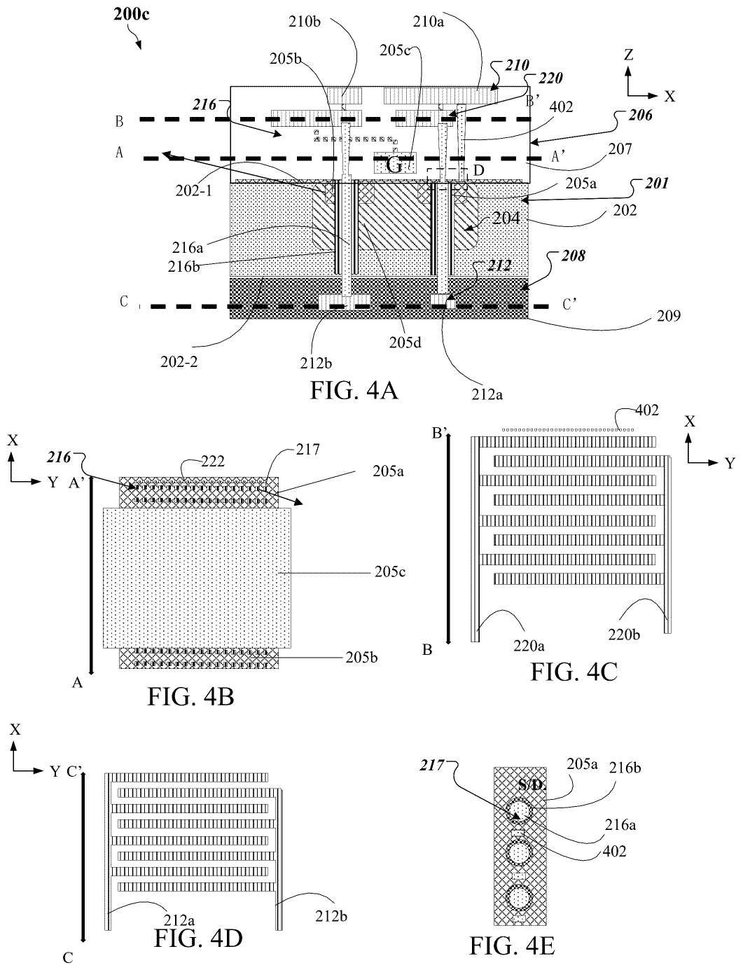

FIG. 4A illustrates across-sectional view (e.g., in the XZ plane) of example 3D semiconductor device 200c. One or more of 3D semiconductor devices 200c can be similar to, or same as, a part of the 3D semiconductor device 100 of FIG. 1 (e.g., the MOMCAP 113 of FIG. 1). The semiconductor device 200c can be similar to the semiconductor device 200a of FIG. 2A and semiconductor device 200b of FIG. 2B except for the second conductive structure 216.

As shown in FIG. 4A, the second conductive structure 216 extends from the first interconnect layer 206, through the semiconductor structure 201, into the second interconnect layer 208, where the second conductive structure 216 extends through the first terminal 205a of the transistor 204, the second terminal 205b of the transistor 204, and the semiconductor layer 202 of the semiconductor structure 201. In some implementations, the conductive fillings 216a of the second conductive structures 216 is connected to one or the electrodes 212a, 212b of the second metal structure 212 and the second electrode 210b of the first metal structure 210 along the Z direction. In some implementations, as shown in FIG. 4A, the first electrode 210a of the first metal structure 210 is electrically coupled to the first terminal 205a of the transistor 204 through a coupling structure 402.

FIG. 4B illustrates a top view of the example 3D semiconductor device 200c of FIG. 4A along cut line AA′ of FIG. 4A. As shown in FIG. 4B, a portion of the outer layer 216b of the second conductive structure 216 extends through the first terminal 205a and the second terminal 205b of the transistor 204 is formed with a high-k material. The first terminal 205a and the second terminal 205b of the transistor 204 is in contact with the outer layer 216b of the second conductive structure 216. In some implementations, the first metal structure 210 and the second metal structure 212 are electrically coupled together through the second conductive structure 216 to increase the capacitance of the semiconductor device 200c. In some implementations, as shown in FIG. 4B, the second conductive structure 216 can include a plurality of vias 217 that extend into the semiconductor structure 201, where the second conductive structure 216 extends intermittently along the horizontal directions.

FIG. 4C illustrates a top view of the example 3D semiconductor device 200c of FIG. 4A along cut line BB′ of FIG. 4A. In some implementations, the semiconductor device 200c can further include a third metal structure 220. As shown in FIG. 4A, the third metal structure 220 is stacked between the semiconductor structure 201 and the first metal structure 210 in the first interconnect layer 206 along the Z direction. In some implementations, the third metal structure 220 is spaced from the semiconductor layer and the first metal structure along the Z direction. As shown in FIG. 4A, the second conductive structure 216 extends through the third metal structure 220 along the Z direction. In some implementations, as shown in FIG. 4C, third metal structure 220 can include a fifth electrode 220a and a sixth electrode 220b separated from each other along the Y direction. The fifth electrode 220a and the sixth electrode 220b of the third metal structure 220 have a plurality of electrical fingers alternating with each other along a second horizontal direction (e.g., the Y direction) perpendicular to the X direction and the Z direction.

FIG. 4D illustrates a top view of the example 3D semiconductor device 200c of FIG. 4A along cut line CC′ of FIG. 4A. As shown in FIG. 4D, the third electrode 212a and the fourth electrode 212b of the second metal structure 212 have a plurality of electrical fingers alternating with each other along a second horizontal direction (e.g., the Y direction) perpendicular to the X direction and the Z direction.

FIG. 4E illustrates a top view of the example 3D semiconductor device 200c zoomed in on Zone D of FIG. 4A. As shown in FIG. 4E, the conductive filling 216a of the second conductive structure 216 is surrounded by the outer layer 216b in the first terminal 205a of the transistor. The coupling structure 402 is between two adjacent vias 217 of the second conductive structure 216.

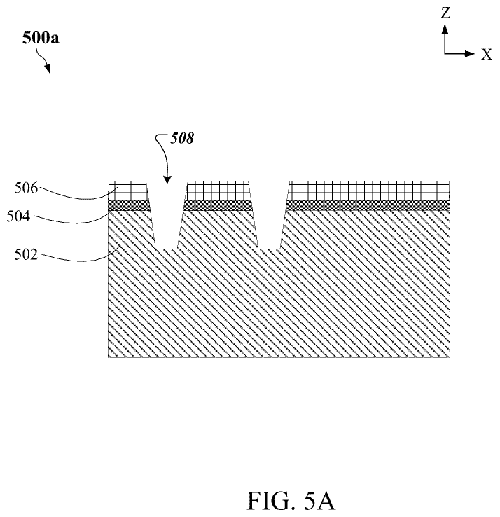

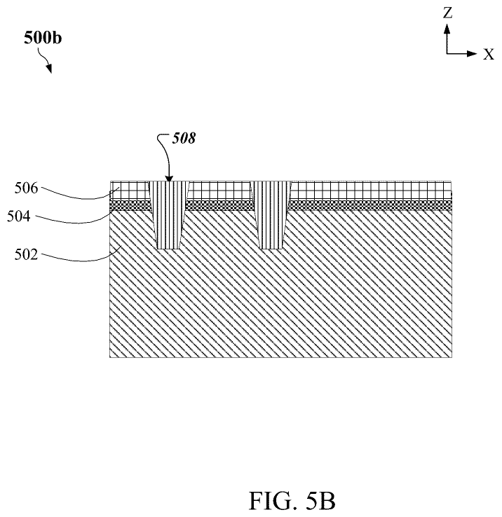

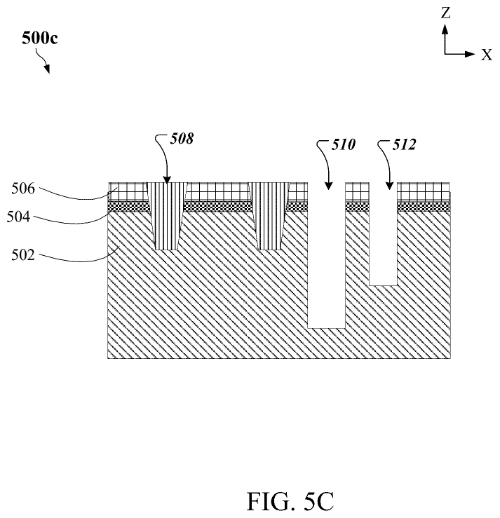

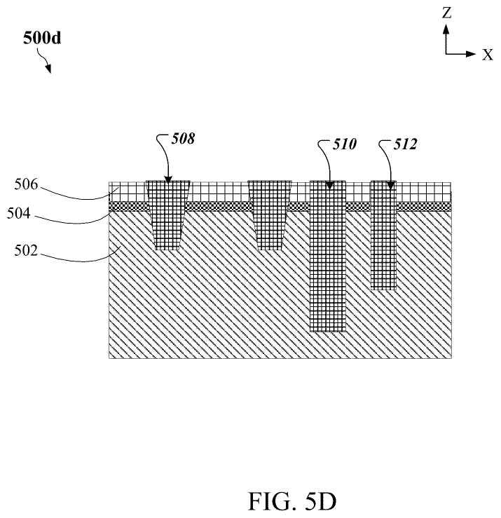

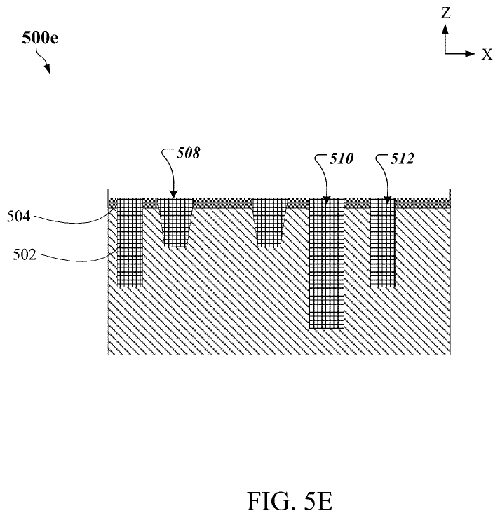

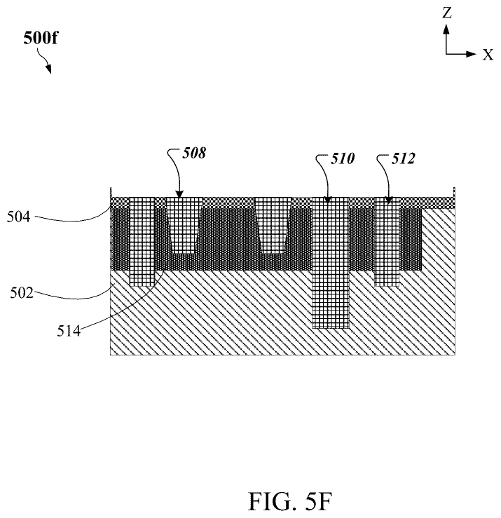

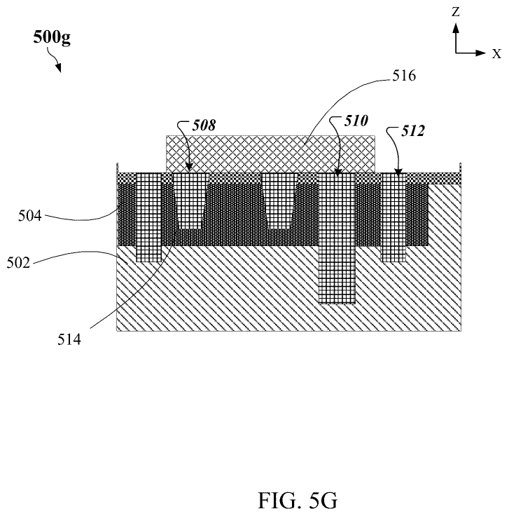

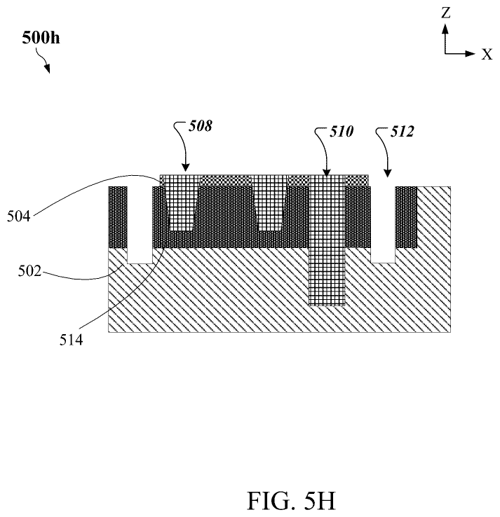

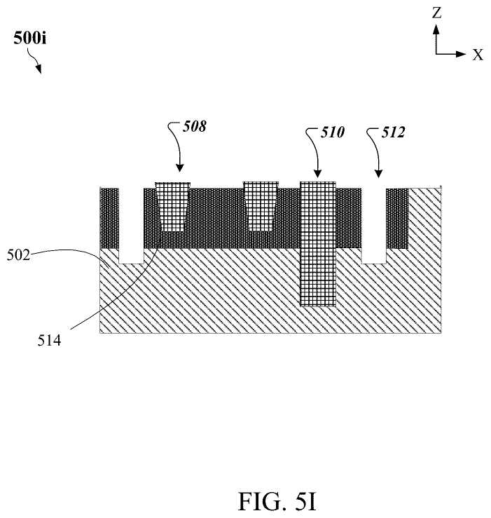

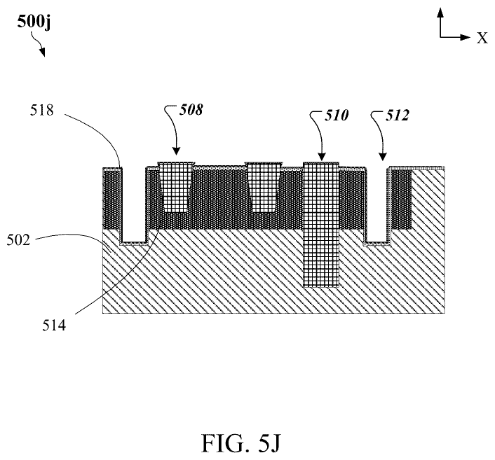

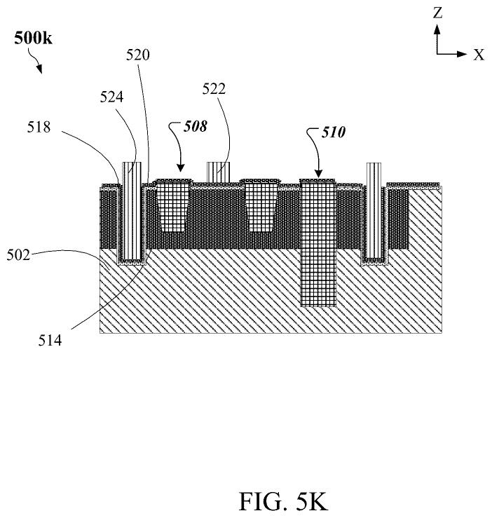

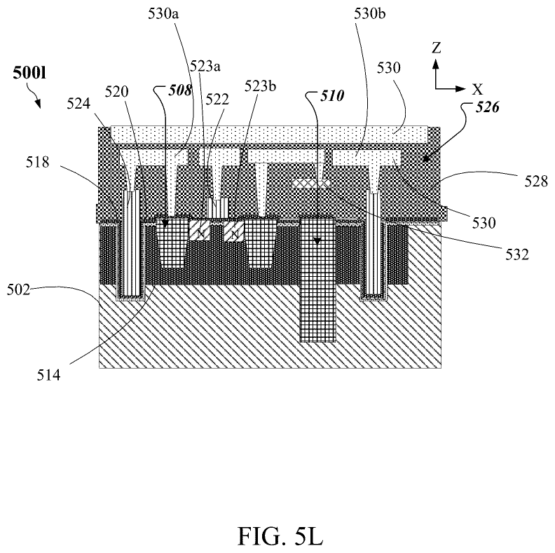

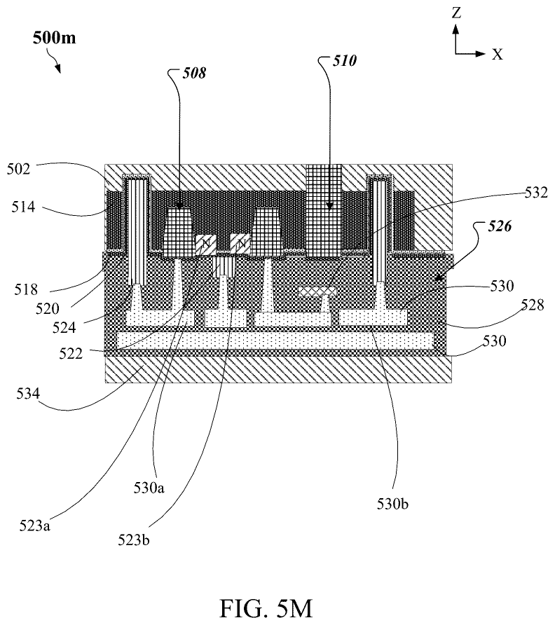

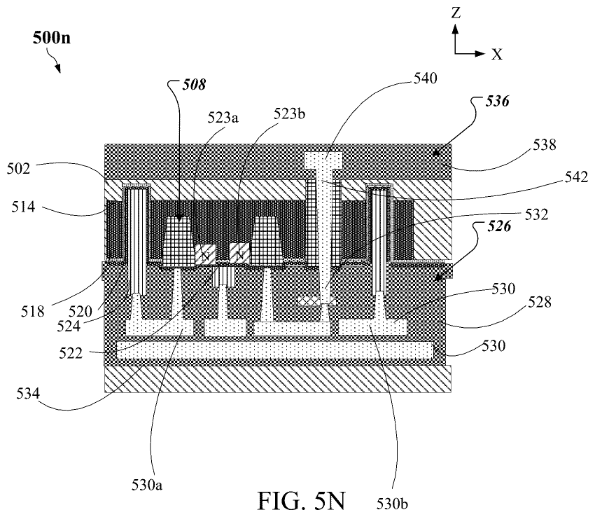

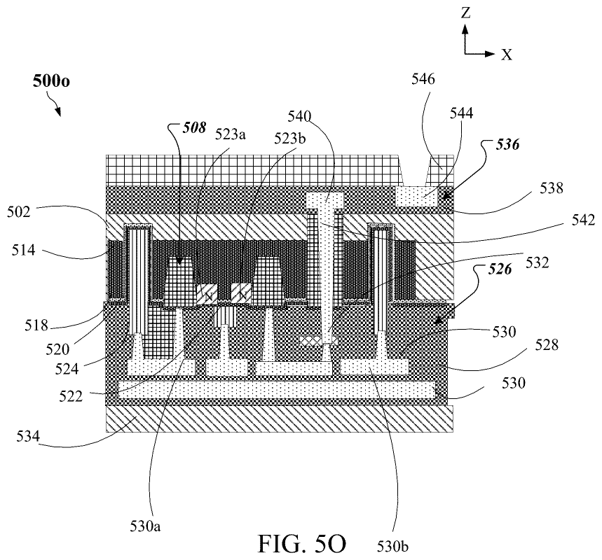

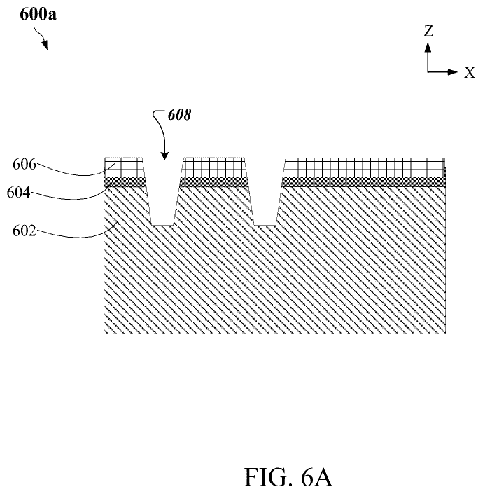

FIGS. 5A-5O illustrate an example process of fabricating a semiconductor device, such as the semiconductor device 200a as illustrated in FIGS. 2A-2D. FIGS. 5A-5O show cross sectional views of example semiconductor structures at various stages of the fabrication process.

FIG. 5A illustrates a semiconductor structure 500a, which can be formed by etching a portion of a semiconductor substrate 502, a first sacrificial layer 504, and a second sacrificial layer 506 along a vertical direction (e.g., the Z direction) to form first trenches 508.

FIG. 5B illustrates a semiconductor structure 500b, which can be formed by depositing a first dielectric material (e.g., SiO2) into the first trenches 508.

FIG. 5C illustrates a semiconductor structure 500c. The semiconductor 500c includes a second trench 510 and a third trench 512, which can be formed by etching a portion of the semiconductor substrate 502, the first sacrificial layer 504, and the second sacrificial layer 506 along the Z direction. The first trenches 508, the second trench 510 and third trench 512 are spaced from each other along a horizontal direction (e.g., the X direction) perpendicular to the Z direction. In some implementations, along the Z direction, a length of the second trench 510 is greater than a length of the third trench 512, and the length of the third trench 512 is greater than a length of the first trenches 508.

FIG. 5D illustrates a semiconductor structure 500d, which can be formed by depositing the first dielectric material (e.g., SiO2) into the second trench 510 and the third trench 512.

FIG. 5E illustrates a semiconductor structure 500e, which can be formed by which can be formed by performing a planarization process, such as chemical mechanical polishing (CMP), to remove the second sacrificial layer 506 and a portion of the trenches 508, 510, 512.

FIG. 5F illustrates a semiconductor structure 500f, which can be formed by implanting a dopant in the semiconductor substrate to form a well region 514. In some implementations, the second trench 510 and the third trench 512 extend though the well region 514. In some implementations, the first trenches 508 extend into the well region 514, where, along the Z direction, a length of the well region 514 is greater than the length of the first trenches 508.

FIG. 5G illustrates a semiconductor structure 500g, which can be formed by depositing a photoresist layer 516 on top of the semiconductor structure 500f. The photoresist layer 516 extends along the X direction and covers the first trenches 508 and the second trench 510.

FIG. 5H illustrates a semiconductor structure 500h, which can be formed by removing the photoresist layer 516, the first dielectric material in the third trench 512 and a portion of the first sacrificial layer 504 through an etching process.

FIG. 5I illustrates a semiconductor structure 500i, which can be formed by removing the first sacrificial layer 504 through an etching process.

FIG. 5J illustrates a semiconductor structure 500j, which can be formed by depositing a dielectric material on a surface of the semiconductor structure 500i and an inner wall of the third trench 512 to form an isolation layer 518.

FIG. 5K illustrates a semiconductor structure 500k. The semiconductor structure 500k includes a first dielectric layer 520, which can be formed by depositing a high-k material on the isolation layer 518. In some implementations, the first dielectric layer 520 can include a high-k material including, but not limited to, hafnium dioxide (HfO2), Zirconium dioxide (ZrO2) and titanium dioxide (TiO2) or any combinations thereof. The semiconductor structure 500k can include a first terminal 522, which can be formed by depositing a conductive material on the first dielectric layer. In some implementations, the first terminal 522 is between two adjacent first trenches 508. The semiconductor structure 500k can also include a first conductive structure 524, which can be formed by depositing a conductive material in the third trench 512.

FIG. 5L illustrates a semiconductor structure 500l. The semiconductor structure 500l can include a second terminal 523a and a third terminal 523b, which can be formed by implementing a dopant in the well region 514. In some implementations, the second terminal 523a and the third terminal 523b are between two adjacent first trenches 508, and the first terminal 522 is between the second terminal 523a and the third terminal 523b along the X direction. The semiconductor structure 500l can also include a first interconnect layer 526. The first interconnect layer 526 can include a second dielectric layer 528, which can be formed by depositing a dielectric material on a surface of the semiconductor structure, where the second dielectric layer 528 is connected to first dielectric layer 520. In some implementations, the first interconnect layer 526 can include a first metal structure 530, which can be formed by depositing a conductive material in the first interconnect layer 526. The first metal structure 530 is connected to the first conductive structure 524, the first terminal 522, and the first trenches 508. In some implementations, the first interconnect structure can include a plurality of first metal structures 530 stacked on top of each other along the Z direction. In some implementations, the first interconnect layer 526 can also include a second metal structure 532, which can be formed by depositing a conductive material in the first interconnect layer 526. The second metal structure 532 is in between the first metal structure 530 and the semiconductor substrate 502 along the Z direction, and the second metal structure 532 is connected to the first metal structure 530. In some implementations, the first metal structure 530 can include a first electrode 530a and a second electrode 530b, where the first electrode 530a of the first metal structure 530 is electrically coupled to the second terminal 523a and the second electrode 530b of the first metal structure 530 is electrically coupled to the first conductive structure 524 and the first terminal 522.

FIG. 5M illustrates a semiconductor structure 500m, which can be formed by bonding a carrier wafer 534 connected to the first interconnect layer 526 and thinning down the semiconductor substrate 502 from a side of the semiconductor substrate 502 farther away from the first interconnect layer 526 along the Z direction.

FIG. 5N illustrates a semiconductor structure 500n. The semiconductor structure 500n includes a second interconnect layer 536. The second interconnect layer 536 can include a third dielectric layer 538, which can be formed by depositing a dielectric material on a surface of the semiconductor structure 500m, the surface of the semiconductor structure 500m being farther away from the first interconnect layer 526. The third dielectric layer is connected to the semiconductor substrate 502. In some implementations, the second interconnect layer 536 can include a third metal structure 540, which can be formed by depositing a conductive material in the second interconnect layer 536. The semiconductor structure 500n can also include a second conductive structure 542, which is formed by etching through a portion of the second trench 510 and depositing a conductive material in the etched region. The second conductive structure 542 is connected to the second metal structure 532 and the third metal structure 540 along the first direction. In some implementations, the second conductive structure 542 is electrically coupled to the first electrode 530a of the first metal structure 530 through the second metal structure 532.

FIG. 5O illustrates a semiconductor structure 500o, which can be formed by depositing a conductive material in a portion of the second interconnect layer 536 to form a pad-out structure 544. The semiconductor structure 500o also includes a fourth dielectric layer 546, which can be formed by depositing a dielectric material on a surface of the semiconductor structure 500n, the surface of the semiconductor structure 500n being closer to the second interconnect layer 536 than the first interconnect layer 526 along the first direction. In some implementations, the pad-out structure 544 is electrically coupled to the third metal structure 540. In some implementations, the carrier wafer 534 can be removed from the semiconductor structure 500o.

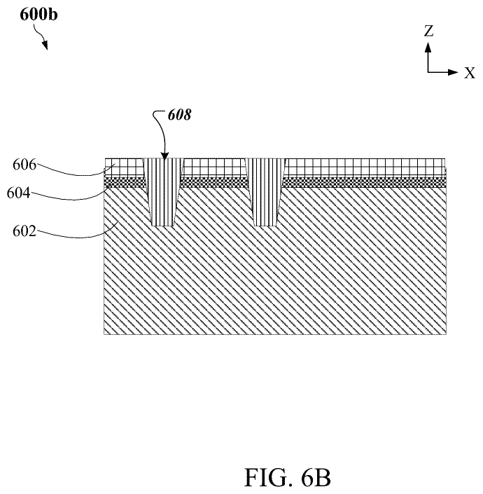

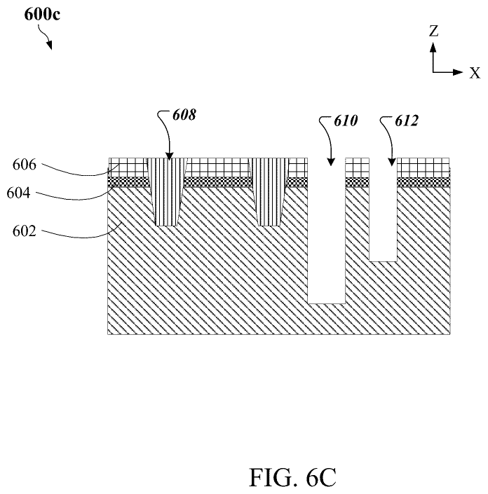

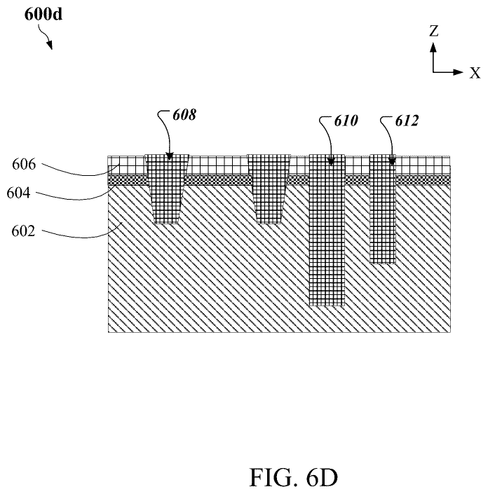

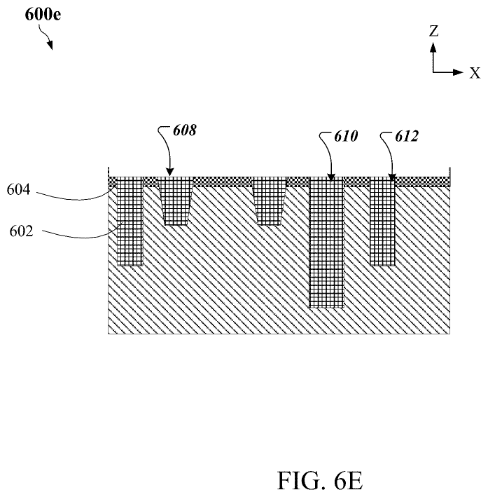

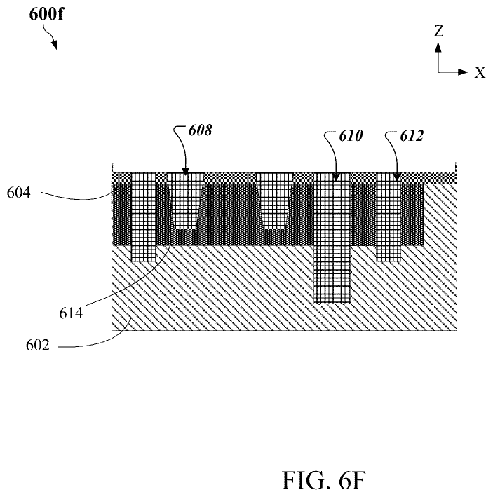

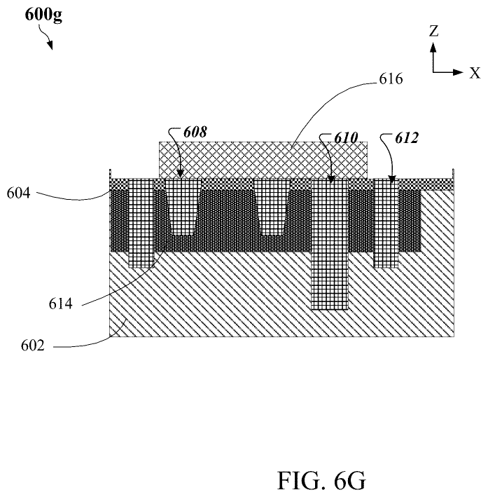

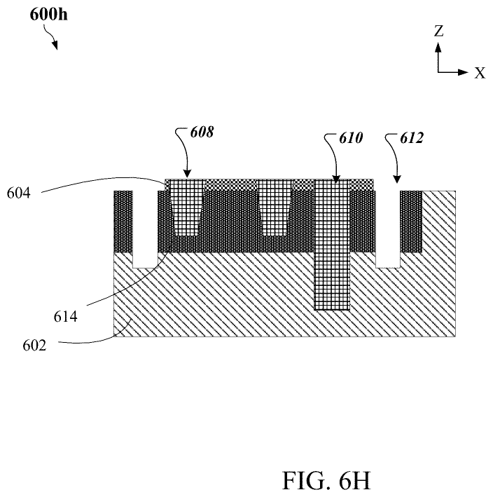

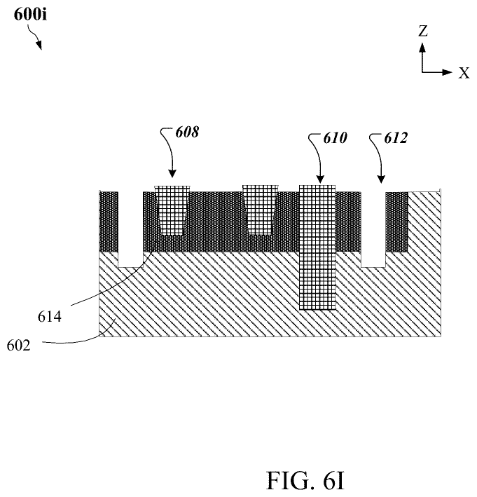

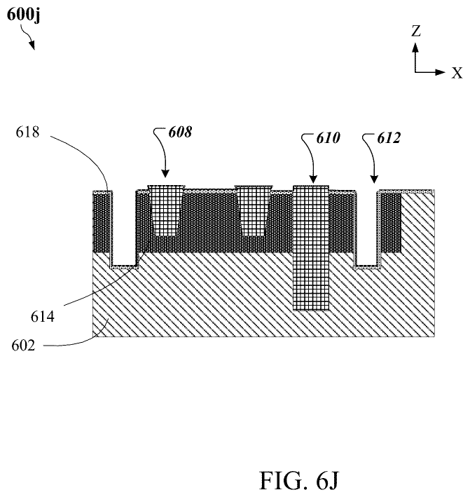

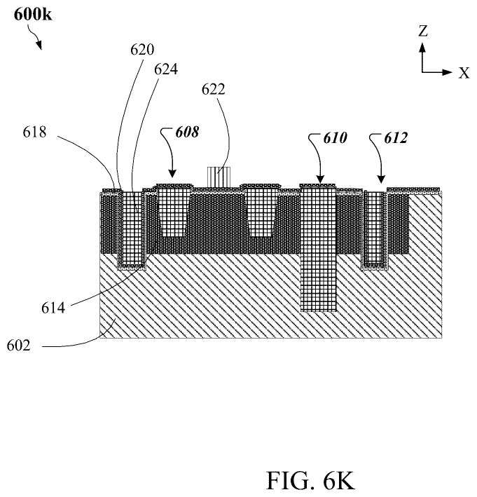

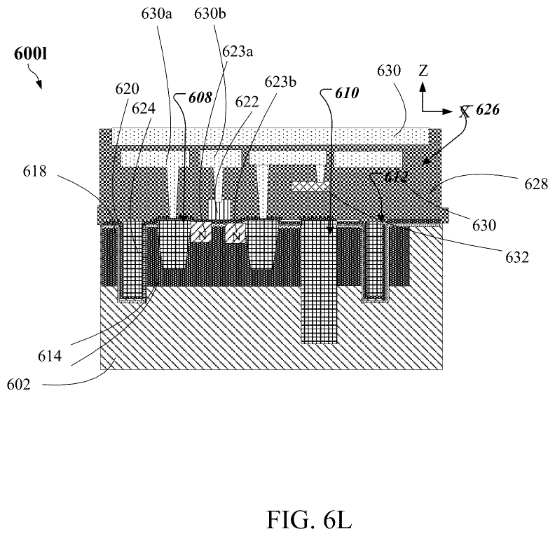

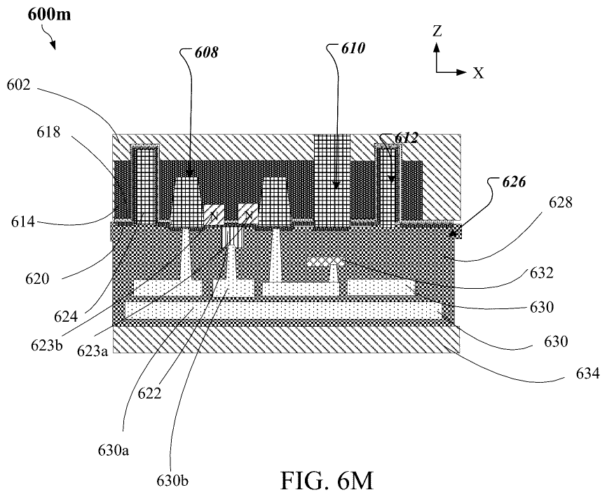

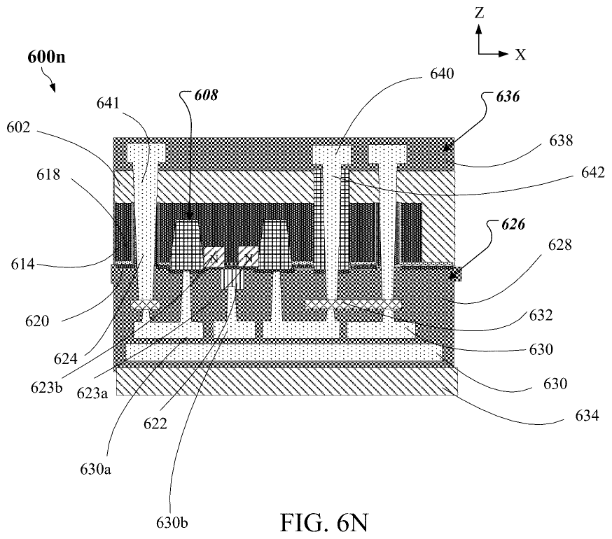

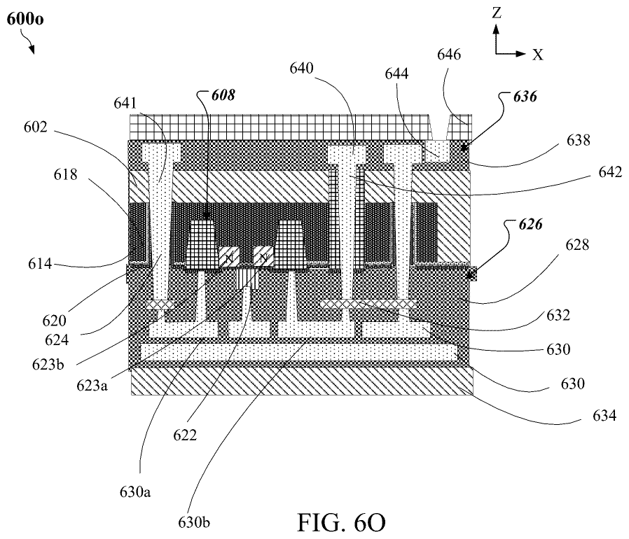

FIGS. 6A-6N illustrate an example process of fabricating a semiconductor device, such as the semiconductor device 200b as illustrated in FIGS. 3A-3D. FIGS. 6A-6N show cross sectional views of example semiconductor structures at various stages of the fabrication process.

FIG. 6A illustrates a semiconductor structure 600a, which can be formed by etching a portion of a semiconductor substrate 602, a first sacrificial layer 604, and a second sacrificial layer 606 along a vertical direction (e.g., the Z direction) to form first trenches 608.

FIG. 6B illustrates a semiconductor structure 600b, which can be formed by depositing a first dielectric material (e.g., SiO2) into the first trenches 608.

FIG. 6C illustrates a semiconductor structure 600c. The semiconductor structure 600c includes a second trench 610 and a third trench 612, which can be formed by etching a portion of the semiconductor substrate 602, the first sacrificial layer 604, and the second sacrificial layer 606 along the Z direction. The first trenches 608, the second trench 610 and third trench 612 are spaced from each other along a horizontal direction (e.g., the X direction) perpendicular to the Z direction. In some implementations, along the Z direction, a length of the second trench 610 is greater than a length of the third trench 612, and the length of the third trench 612 is greater than a length of the first trenches 608.

FIG. 6D illustrates a semiconductor structure 600d, which can be formed by depositing the first dielectric material (e.g., SiO2) into the second trench 610 and the third trench 612.

FIG. 6E illustrates a semiconductor structure 600e, which can be formed by which can be formed by performing a planarization process, such as chemical mechanical polishing (CMP), to remove the second sacrificial layer 606 and a portion of the trenches 608, 610, 612.

FIG. 6F illustrates a semiconductor structure 600f, which can be formed by implanting a dopant in the semiconductor substrate to form a well region 614. In some implementations, the second trench 610 and the third trench 612 extend though the well region 614. In some implementations, the first trenches 608 extend into the well region 614, where, along the Z direction, a length of the well region 614 is greater than the length of the first trenches 608.

FIG. 6G illustrates a semiconductor structure 600g, which can be formed by depositing a photoresist layer 616 on top of the semiconductor structure 600f. The photoresist layer 616 extends along the X direction and covers the first trenches 608 and the second trench 610.

FIG. 6H illustrates a semiconductor structure 600h, which can be formed by removing the photoresist layer 616, the first dielectric material in the third trench 612 and a portion of the first sacrificial layer 604 through an etching process.

FIG. 6I illustrates a semiconductor structure 600i, which can be formed by removing the first sacrificial layer 604 through an etching process.

FIG. 6J illustrates a semiconductor structure 600j, which can be formed by depositing a dielectric material on a surface of the semiconductor structure 600i and an inner wall of the third trench 612 to form an isolation layer 618.

FIG. 6K illustrates a semiconductor structure 600k. The semiconductor structure 600k includes a first dielectric layer 620, which can be formed by depositing a high-k material on the isolation layer 618. In some implementations, the first dielectric layer 620 can include a high-k material including, but not limited to, hafnium dioxide (HfO2), Zirconium dioxide (ZrO2) and titanium dioxide (TiO2) or any combinations thereof. The semiconductor structure 600k can include a first terminal 622, which can be formed by depositing a conductive material on the first dielectric layer. In some implementations, the first terminal 622 is between two adjacent first trenches 608. The semiconductor structure 600k can also include a filled structure 624, which can be formed by depositing a conductive material in the third trench 612.

FIG. 6L illustrates a semiconductor structure 600l. The semiconductor structure 600l can include a second terminal 623a and a third terminal 623b, which can be formed by implementing a dopant in the well region 614. In some implementations, the second terminal 623a and the third terminal 623b are between two adjacent first trenches 608, and the first terminal 622 is between the second terminal 623a and the third terminal 623b along the X direction. The semiconductor structure 600l can also include a first interconnect layer 626. The first interconnect layer 626 can include a second dielectric layer 628, which can be formed by depositing a dielectric material on a surface of the semiconductor structure, where the second dielectric layer 628 is connected to first dielectric layer 620. In some implementations, the first interconnect layer 626 can include a first metal structure 630, which can be formed by depositing a conductive material in the first interconnect layer 626. The first metal structure 630 is connected to the first terminal 622, and the first trenches 608. In some implementations, the first interconnect structure can include a plurality of first metal structures 630 stacked on top of each other along the Z direction. In some implementations, the first interconnect layer 626 can also include a second metal structure 632, which can be formed by depositing a conductive material in the first interconnect layer 626. The second metal structure 632 is in between the first metal structure 630 and the semiconductor substrate 602 along the Z direction, and the second metal structure 632 is connected to the first metal structure 630. In some implementations, the first metal structure 630 can include a first electrode 630a and a second electrode 630b, where the first electrode 630a of the first metal structure 630 is electrically coupled to the second terminal 623a and the second electrode 630b of the first metal structure 630 is electrically coupled to the first terminal 622.

FIG. 6M illustrates a semiconductor structure 600m, which can be formed by bonding a carrier wafer 634 connected to the first interconnect layer 626 and thinning down the semiconductor substrate 602 from a side of the semiconductor substrate 602 farther away from the first interconnect layer 626 along the Z direction.

FIG. 6N illustrates a semiconductor structure 600n. The semiconductor structure 600n includes a second interconnect layer 636. The second interconnect layer 636 can include a third dielectric layer 638, which can be formed by depositing a dielectric material on a surface of the semiconductor structure 600m, the surface of the semiconductor structure 600m being farther away from the first interconnect layer 626. The third dielectric layer is connected to the semiconductor substrate 602. In some implementations, the second interconnect layer 636 can include a third metal structure 640, which can be formed by depositing a conductive material in the second interconnect layer 636. The semiconductor structure 600n can include a first conductive structure 641, which is formed by etching through a portion of the third trench 612 and depositing a conductive material in the etched region, the first conductive structure 641 is connected to the third metal structure 640 along the Z direction. In some implementations, the first conductive structure 641 is electrically coupled to the second electrode 630b of the first metal structure 630 through the second metal structure 632 along the Z direction. The semiconductor structure 600n can also include a second conductive structure 642, which is formed by etching through a portion of the second trench 610 and depositing a conductive material in the etched region. The second conductive structure 642 is connected to the second metal structure 632 and the third metal structure 640 along the first direction. In some implementations, the second conductive structure 642 is electrically coupled to the first electrode 630a of the first metal structure 630 through the second metal structure 632.

FIG. 6O illustrates a semiconductor structure 600o, which can be formed by depositing a conductive material in a portion of the second interconnect layer 636 to form a pad-out structure 644. The semiconductor structure 600o also includes a fourth dielectric layer 646, which can be formed by depositing a dielectric material on a surface of the semiconductor structure 600n, the surface of the semiconductor structure 600n being closer to the second interconnect layer 636 than the first interconnect layer 626 along the first direction. In some implementations, the pad-out structure 644 is electrically coupled to the third metal structure 640. In some implementations, the carrier wafer 634 can be removed from the semiconductor structure 600o.

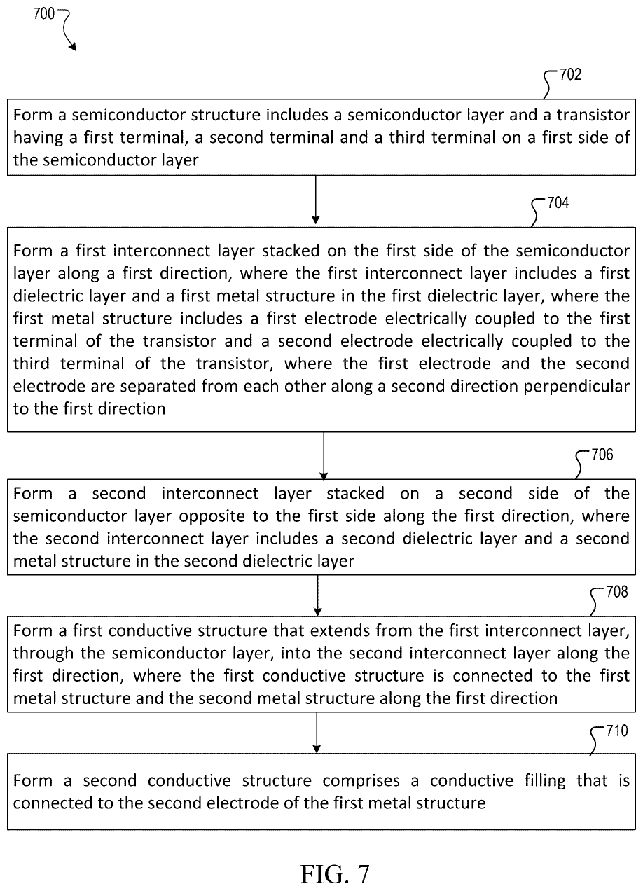

FIG. 7 illustrates a flow chart of an example process 700 of manufacturing a semiconductor structure. The process 700 can be performed to form a semiconductor device (e.g., the semiconductor device 200a of FIG. 2A, the semiconductor device 200b of FIG. 2B, and the semiconductor device 200c of FIG. 2C). The process 700 can be described in view of FIGS. 5A-5O or FIGS. 6A-6O. The process 700 can include one or more steps of the fabrication process of forming the semiconductor structures in FIGS. 5A-5O or FIGS. 6A-6O. It is understood that the operations shown in process 700 are not exhaustive and that other operations can be performed as well before, after, or between any of the illustrated operations. Further, some of the operations may be performed simultaneously, or in a different order than shown in FIG. 7.

At operation 702, a semiconductor structure (e.g., the semiconductor structure 201 of FIG. 2A) is formed. The semiconductor structure includes a semiconductor layer (e.g., the semiconductor substrate 502 of FIG. 5A and semiconductor substrate 602 of FIG. 6A) and a transistor (e.g., the transistor 204 of FIG. 2A) having a first terminal (e.g., the second terminal 523a of FIG. 5L and the second terminal 623a of FIG. 6L), a second terminal (e.g., the third terminal 523b of FIG. 5L and the third terminal 623b of FIG. 6L)and a third terminal (e.g., the first terminal 522 of FIG. 5K and the first terminal 622 of FIG. 6K) on a first side of the semiconductor layer.

At operation 704, a first interconnect layer (e.g., the first interconnect layer 526 of FIG. 5L and the first interconnect layer 626 of FIG. 6L) is formed. The first interconnect layer stacked on the first side of the semiconductor layer along a first direction (e.g., the Z direction), where the first interconnect layer includes a first dielectric layer (e.g., the second dielectric layer 528 of FIG. 5L and the second dielectric layer 628 of FIG. 6L) and a first metal structure (e.g., the first metal structure 530 of FIG. 5L and the first metal structure 630 of FIG. 6L) in the first dielectric layer, where the first metal structure includes a first electrode (e.g., the first electrode 530a of FIG. 5L and the first electrode 630a of FIG. 6L) electrically coupled to the first terminal of the transistor and a second electrode (e.g., the second electrode 530b of FIG. 5L and the second electrode 630b of FIG. 6L) electrically coupled to the third terminal of the transistor, where the first electrode and the second electrode are separated from each other along a second direction (e.g., the X direction) perpendicular to the first direction.

At operation 706, a second interconnect layer (e.g., the second interconnect layer 536 of FIG. 5N and the second interconnect layer 636 of FIG. 6N) is formed. The second interconnect layer stacked on a second side of the semiconductor layer opposite to the first side along the first direction, where the second interconnect layer includes a second dielectric layer (e.g., the third dielectric layer 538 of FIG. 5N and the third dielectric layer 638 of FIG. 6N) and a second metal structure (e.g., the third metal structure 540 of FIG. 5N and the third metal structure 640 of FIG. 6N) in the second dielectric layer.

At operation 708, a first conductive structure (e.g., the second conductive structure 542 of FIG. 5N and the second conductive structure 642 of FIG. 6N) is formed. The first conductive structure extends from the first interconnect layer, through the semiconductor layer, into the second interconnect layer along the first direction, where the first conductive structure is connected to the first metal structure and the second metal structure along the first direction.

At operation 710 a second conductive structure (e.g., the first conductive structure 524 of FIG. 5K and the first conductive structure 641 of FIG. 6N) is formed. The second conductive structure includes a conductive filling (e.g., the conductive filling 214a of FIG. 2A) that is connected to the second electrode of the first metal structure.

In some implementations, forming the transistor includes etching a portion of the semiconductor layer along the first direction to form first spaces (e.g., the first trenches 508 of FIG. 5A and the first trenches 608 of FIG. 6A); etching a portion of the semiconductor layer along the first direction to form a second space (e.g., the second trench 510 of FIG. 5C and the second trench 610 of FIG. 6C), where the second space and the first spaces are separated from each other along the second direction; filling a dielectric material into the first spaces and the second space to from first filled spaces and a second filled space; and forming the transistor a first terminal (e.g., the second terminal 523a of FIG. 5L and the second terminal 623a of FIG. 6L), a second terminal (e.g., the third terminal 523b of FIG. 5L and the third terminal 623b of FIG. 6L)and a third terminal (e.g., the first terminal 522 of FIG. 5K and the first terminal 622 of FIG. 6K) between two adjacent first filled spaces along the second direction.

In some implementations, the second conductive structure extends from the first interconnect layer into the semiconductor layer, and where the operation further includes etching a third portion of the semiconductor layer along the first direction to form a third space (e.g., the third trench 512 of FIG. 5C), where the third space, the first filled spaces, and the second filled space are separated from each other; depositing a high-k material on an inner wall of the third space; filling a conductive material into the third space to form the second conductive structure; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor and is connected to the conductive filling of the second conductive structure; depositing the second interconnect layer on the second side of the semiconductor layer opposite to the first side along the first direction; etching a portion of the second interconnect layer, the second filled space, and the first interconnect layer along the first direction to form a fourth space connected to the first electrode of the first metal structure; depositing a conductive material in the fourth space to form the first conductive structure; and forming the second metal structure having a third electrode and a fourth electrode separated from each other in the second interconnect layer, where the first conductive structure is connected to the first metal structure and the second metal structure along the first direction.

In some implementations, the second conductive structure extends continuously or intermittently, and where the second conductive structure surrounds the transistor.

In some implementations, the second conductive structure extends from the first interconnect layer, through the semiconductor layer, into the second interconnect layer, and where the operation further includes etching a portion of the semiconductor layer along the first direction to form a fifth space (e.g., the third trench 612 of FIG. 6C), where the fifth space, the first filled spaces, and the second filled space are separated from each other; depositing a high-k material on an inner wall of the fifth space; filling the fifth space with a dielectric material to from a fifth filled space; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor; depositing the second interconnect layer on the second side of the semiconductor layer opposite to the first side along the first direction; etching a portion of the second interconnect layer, the second filled space, and the first interconnect layer along the first direction to form a sixth space connected to the first electrode of the first metal structure; etching a portion of the second interconnect layer, the semiconductor layer, the fifth filled space, and the first interconnect layer to from a seventh space connected to the second electrode of the first metal structure; depositing a conductive material in the sixth space and the seventh space to from the first conductive structure and the second conductive structure; and forming the second metal structure having a third electrode and a fourth electrode separated from each other in the second interconnect layer, where the first conductive structure is connected to the first metal structure and the second metal structure along the first direction, and where the second conductive structure is connected to the second electrode of the first metal structure and one of the electrodes of the second metal structure.

In some implementations, the second conductive structure extends through the first terminal of the transistor, the second terminal of the transistor, the semiconductor layer and into the second interconnect layer, and where the operation further includes etching a portion of the semiconductor layer along the first direction to form an eighth space, where the eighth space, the first filled spaces, and the second filled space are separated from each other, and where the eighth space is between the two adjacent first filled spaces and the eighth space extends through the first terminal and the second terminal of the transistor; depositing a high-k material on an inner wall of the eighth space; filling the eighth space with a dielectric material to from an eighth filled space, where the eighth filled space is between two adjacent first filled space; depositing the first interconnect layer connected to the transistor on the first side of the semiconductor layer along the first direction; forming the first metal structure in the first interconnect layer, where the first metal structure includes the first electrode electrically coupled to the first terminal of the transistor and the second electrode electrically coupled to the third terminal of the transistor; depositing the second interconnect layer on the second side of the semiconductor layer opposite to the first side along the first direction; etching a portion of the second interconnect layer, the second filled space, and the first interconnect layer along the first direction to form a ninth space connected to the first electrode of the first metal structure; etching a portion of the second interconnect layer, the semiconductor layer, the eighth filled space, and the first interconnect layer to from a tenth space connected to the second electrode of the first metal structure; depositing a conductive material in the ninth space and the tenth space to from the first conductive structure and the second conductive structure; and forming the second metal structure having a third electrode and a fourth electrode separated from each other in the second interconnect layer, where the first conductive structure is connected to the first metal structure and the second metal structure along the first direction, and where the second conductive structure is connected to the second electrode of the first metal structure and one of the electrodes of the second metal structure.

In some implementations, the operation further includes forming a third metal structure (e.g., the second metal structure 532 of FIG. 5L and the second metal structure 632 of FIG. 6L) in the first interconnect layer having a fifth electrode and a sixth electrode separated from each other, where the third metal structure is stacked between the semiconductor layer and the first metal structure along the first direction, and the third metal structure is spaced from the semiconductor layer and the first metal structure along the first direction, and where the first electrode of the first metal structure is electrically coupled to the first terminal of the transistor through the fifth electrode and the second electrode of the first metal structure is electrically coupled to the third terminal of the transistor through the sixth electrode.

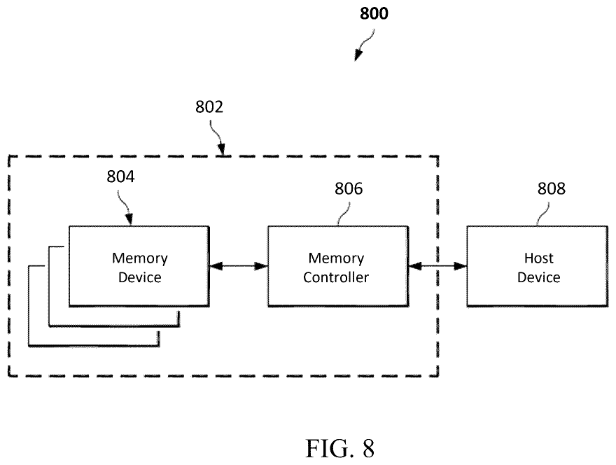

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

A 3D memory device 804 can be any 3D memory device disclosed herein, such as 3D memory device depicted in FIG. 1. In some implementations, a 3D memory device 804 includes a NAND Flash memory. Memory controller 806 (a.k. a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +−.10%,. +−.20%, or. +−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a semiconductor structure comprises a semiconductor layer and a transistor having a first terminal, a second terminal and a third terminal on a first side of the semiconductor layer;
a first interconnect layer stacked on the first side of the semiconductor layer along a first direction, wherein the first interconnect layer comprises a first dielectric layer and a first metal structure in the first dielectric layer, wherein the first metal structure comprises a first electrode electrically coupled to the first terminal of the transistor and a second electrode electrically coupled to the third terminal of the transistor, wherein the first electrode and the second electrode are separated from each other along a second direction perpendicular to the first direction;
a second interconnect layer stacked on a second side of the semiconductor layer opposite to the first side along the first direction, wherein the second interconnect layer comprises a second dielectric layer and a second metal structure in the second dielectric layer;
a first conductive structure that extends from the first interconnect layer, through the semiconductor layer, into the second interconnect layer along the first direction, wherein the first conductive structure is connected to the first metal structure and the second metal structure along the first direction; and
a second conductive structure comprises a conductive filling that is connected to the second electrode of the first metal structure.

2. The semiconductor device of claim 1, wherein the second metal structure comprises a third electrode and a fourth electrode separated from each other along the second direction.

3. The semiconductor device of claim 1, wherein the second conductive structure comprises an outer layer surrounded the conductive filling.

4. The semiconductor device of claim 3, wherein a portion of the outer layer in the semiconductor layer comprises a high-k material, and a remaining portion of the outer layer of the second conductive structure comprises a dielectric material, and wherein a dielectric constant of the high-k material is greater than a dielectric constant of the dielectric material.

5. The semiconductor device of claim 4, wherein the second conductive structure extends from the first interconnect layer into the semiconductor layer, and wherein, along the first direction, a length of the second conductive structure is no greater than a length of the first conductive structure.

6. The semiconductor device of claim 1, wherein the first conductive structure comprises an inner body and an outer layer, wherein the inner body of the first conductive structure comprises a conductive material and the outer layer of the first conductive structure comprises a dielectric material.

7. The semiconductor device of claim 4, wherein the second conductive structure extends continuously or intermittently, and wherein the second conductive structure surrounds the transistor.

8. The semiconductor device of claim 1, further comprising:
a third metal structure in the first interconnect layer having a fifth electrode and a sixth electrode separated from each other, wherein the third metal structure is stacked between the semiconductor structure and the first metal structure along the first direction, and the third metal structure is spaced from the semiconductor layer and the first metal structure along the first direction, and
wherein the first electrode of the first metal structure is electrically coupled to the first terminal of the transistor through the fifth electrode and the second electrode of the first metal structure is electrically coupled to the third terminal of the transistor through the sixth electrode.

9. The semiconductor device of claim 2, wherein the first electrode and the second electrode of the first metal structure have a plurality of electrical fingers alternating with each other along a third direction perpendicular to the first direction and the second direction, and
wherein the third electrode and the fourth electrode of the second metal structure have a plurality of electrical fingers alternating with each other along the third direction.

10. The semiconductor device of claim 4, wherein the second conductive structure extends from the first interconnect layer, through the semiconductor layer, into the second interconnect layer, and wherein the conductive filling of the second conductive structure is connected to one of the electrodes of the second metal structure along the first direction.

11. The semiconductor device of claim 4, wherein the second conductive structure extends from the first interconnect layer, through the semiconductor structure, into the second interconnect layer, and wherein the conductive filling of the second conductive structure is connected to one of the electrodes of the second metal structure along the first direction.

12. The semiconductor device of claim 11, wherein the second conductive structure extends through the first terminal of the transistor, the second terminal of the transistor and the semiconductor layer,
wherein a portion of the outer layer of the second conductive structure extends through the first terminal and the second terminal of the transistor comprises the high-k material, and
wherein the first terminal and the second terminal of the transistor is in contact with the outer layer of the second conductive structure along the second direction.

13. A method of forming a semiconductor device, the method comprising:
forming a semiconductor structure comprises a semiconductor layer and a transistor having a first terminal, a second terminal and a third terminal on a first side of the semiconductor layer;
forming a first interconnect layer stacked on the first side of the semiconductor layer along a first direction, wherein the first interconnect layer comprises a first dielectric layer and a first metal structure in the first dielectric layer, wherein the first metal structure comprises a first electrode electrically coupled to the first terminal of the transistor and a second electrode electrically coupled to the third terminal of the transistor, wherein the first electrode and the second electrode are separated from each other along a second direction perpendicular to the first direction;
forming a second interconnect layer stacked on a second side of the semiconductor layer opposite to the first side along the first direction, wherein the second interconnect layer comprises a second dielectric layer and a second metal structure in the second dielectric layer;
forming a first conductive structure that extends from the first interconnect layer, through the semiconductor layer, into the second interconnect layer along the first direction, wherein the first conductive structure is connected to the first metal structure and the second metal structure along the first direction; and
forming a second conductive structure comprises a conductive filling that is connected to the second electrode of the first metal structure.

14. The method of claim 13, wherein forming the transistor comprises:
etching a portion of the semiconductor layer along the first direction to form first spaces;
etching a portion of the semiconductor layer along the first direction to form a second space, wherein the second space and the first spaces are separated from each other along the second direction;
filling a dielectric material into the first spaces and the second space to from first filled spaces and a second filled space; and
forming the transistor having a first terminal, a second terminal and a third terminal between two adjacent first filled spaces along the second direction.

15. The method of claim 14, wherein the second conductive structure extends from the first interconnect layer into the semiconductor layer, and wherein the method further comprises:
etching a third portion of the semiconductor layer along the first direction to form a third space, wherein the third space, the first filled spaces, and the second filled space are separated from each other;
depositing a high-k material on an inner wall of the third space;
filling a conductive material into the third space to form the second conductive structure;
depositing the first interconnect layer connected to the transistor on the first side of the semiconductor layer along the first direction;
forming the first metal structure in the first interconnect layer, wherein the first metal structure comprises the first electrode electrically coupled to the first terminal of the transistor and the second electrode electrically coupled to the third terminal of the transistor and is connected to the conductive filling of the second conductive structure;
depositing the second interconnect layer on the second side of the semiconductor layer opposite to the first side along the first direction;
etching a portion of the second interconnect layer, the second filled space, and the first interconnect layer along the first direction to form a fourth space connected to the first electrode of the first metal structure;
depositing a conductive material in the fourth space to form the first conductive structure; and
forming the second metal structure having a third electrode and a fourth electrode separated from each other in the second interconnect layer, wherein the first conductive structure is connected to the first metal structure and the second metal structure along the first direction.

16. The method of claim 15, wherein the second conductive structure extends continuously or intermittently, and wherein the second conductive structure surrounds the transistor.

17. The method or claim 14, wherein the second conductive structure extends from the first interconnect layer, through the semiconductor layer, into the second interconnect layer, and wherein the method further comprises:
etching a portion of the semiconductor layer along the first direction to form a fifth space, wherein the fifth space, the first filled spaces, and the second filled space are separated from each other;
depositing a high-k material on an inner wall of the fifth space;
filling the fifth space with a dielectric material to from a fifth filled space;
depositing the first interconnect layer connected to the transistor on the first side of the semiconductor layer along the first direction;
forming the first metal structure in the first interconnect layer, wherein the first metal structure comprises the first electrode electrically coupled to the first terminal of the transistor and the second electrode electrically coupled to the third terminal of the transistor;
depositing the second interconnect layer on the second side of the semiconductor layer opposite to the first side along the first direction;
etching a portion of the second interconnect layer, the second filled space, and the first interconnect layer along the first direction to form a sixth space connected to the first electrode of the first metal structure;
etching a portion of the second interconnect layer, the semiconductor layer, the fifth filled space, and the first interconnect layer to from a seventh space connected to the second electrode of the first metal structure;
depositing a conductive material in the sixth space and the seventh space to from the first conductive structure and the second conductive structure; and
forming the second metal structure having a third electrode and a fourth electrode separated from each other in the second interconnect layer, wherein the first conductive structure is connected to the first metal structure and the second metal structure along the first direction, and wherein the second conductive structure is connected to the second electrode of the first metal structure and one of the electrodes of the second metal structure.

18. The method of claim 14, wherein the second conductive structure extends through the first terminal of the transistor, the second terminal of the transistor, the semiconductor layer and into the second interconnect layer, and wherein the method further comprises:
etching a portion of the semiconductor layer along the first direction to form an eighth space, wherein the eighth space, the first filled spaces, and the second filled space are separated from each other, and wherein the eighth space is between the two adjacent first filled spaces and the eighth space extends through the first terminal and the second terminal of the transistor;
depositing a high-k material on an inner wall of the eighth space;
filling the eighth space with a dielectric material to from an eighth filled space, wherein the eighth filled space is between two adjacent first filled space;
depositing the first interconnect layer connected to the transistor on the first side of the semiconductor layer along the first direction;
forming the first metal structure in the first interconnect layer, wherein the first metal structure comprises the first electrode electrically coupled to the first terminal of the transistor and the second electrode electrically coupled to the third terminal of the transistor;
depositing the second interconnect layer on the second side of the semiconductor layer opposite to the first side along the first direction;
etching a portion of the second interconnect layer, the second filled space, and the first interconnect layer along the first direction to form a ninth space connected to the first electrode of the first metal structure;
etching a portion of the second interconnect layer, the semiconductor layer, the eighth filled space, and the first interconnect layer to from a tenth space connected to the second electrode of the first metal structure;
depositing a conductive material in the ninth space and the tenth space to from the first conductive structure and the second conductive structure; and
forming the second metal structure having a third electrode and a fourth electrode separated from each other in the second interconnect layer, wherein the first conductive structure is connected to the first metal structure and the second metal structure along the first direction, and wherein the second conductive structure is connected to the second electrode of the first metal structure and one of the electrodes of the second metal structure.

19. The method of claim 13, further comprising:
forming a third metal structure in the first interconnect layer having a fifth electrode and a sixth electrode separated from each other, wherein the third metal structure is stacked between the semiconductor layer and the first metal structure along the first direction, and the third metal structure is spaced from the semiconductor layer and the first metal structure along the first direction, and
wherein the first electrode of the first metal structure is electrically coupled to the first terminal of the transistor through the fifth electrode and the second electrode of the first metal structure is electrically coupled to the third terminal of the transistor through the sixth electrode.

20. A memory system, comprising:
a memory device; and
a memory controller electrically coupled to the memory device and configured to control the memory device,
wherein the memory device comprises:
a semiconductor structure comprises a semiconductor layer and a transistor having a first terminal, a second terminal and a third terminal on a first side of the semiconductor layer;
a first interconnect layer stacked on the first side of the semiconductor layer along a first direction, wherein the first interconnect layer comprises a first dielectric layer and a first metal structure in the first dielectric layer, wherein the first metal structure comprises a first electrode electrically coupled to the first terminal of the transistor and a second electrode electrically coupled to the third terminal of the transistor, wherein the first electrode and the second electrode are separated from each other along a second direction perpendicular to the first direction;
a second interconnect layer stacked on a second side of the semiconductor layer opposite to the first side along the first direction, wherein the second interconnect layer comprises a second dielectric layer and a second metal structure in the second dielectric layer;
a first conductive structure that extends from the first interconnect layer, through the semiconductor layer, into the second interconnect layer along the first direction, wherein the first conductive structure is connected to the first metal structure and the second metal structure along the first direction; and
a second conductive structure comprises a conductive filling that is connected to the second electrode of the first metal structure.
